(19) United States
(12) Patent Application Publication
(10) Pub. No.: US 2018/0166511 A1
(43) Pub. Date: Jun. 14, 2018

(54) DISPLAY DEVICE AND METHOD FOR MANUFACTURING DISPLAY DEVICE

(71) Applicant: Sharp Kabushiki Kaisha, Sakai City, Osaka (JP)

(72) Inventors: Manabu NIBOSHI, Sakai City (JP); Shinichi KAWATO, Sakai City (JP); Satoshi INOUE, Sakai City (JP); Yuhki KOBAYASHI, Sakai City (JP)

(21) Appl. No.: 15/735,298

(22) PCT Filed: Jul. 12, 2016
(86) PCT No.: PCT/JP2016/070603

§ 371 Date: Dec. 11, 2017

(30) Foreign Application Priority Data
Jul. 14, 2015 (JP) 2015-140786

(51) Int. Cl. H01L 27/32; G02B 5/20; H01L 51/52; H01L 51/50

(52) U.S. Cl. CPC H01L 27/3211; H01L 51/5072; H01L 51/5203; G02B 5/20

(57) ABSTRACT

Provided is a display device with high productivity and with reduced color shift in light-emitting elements and reduced degradation in light-emitting element characteristics. An electron transport film (4c) formed on a blue light-emitting film (4b) in B pixels is thicker than an electron transport film (6d) formed on a green light-emitting film (6b) and a red light-emitting film (6c) in G and R pixels so that the remaining film percentage of the electron transport film (4c) after exposure to heat generated by irradiation with laser light is higher than the remaining film percentage of the electron transport film (6d) after exposure to heat generated by irradiation with laser light.

### TECHNICAL FIELD

The present invention relates to display devices, and particularly to organic EL display devices and methods for manufacturing such display devices.

### BACKGROUND ART

Recently, various flat panel displays have been developed. In particular, organic electroluminescence (EL) display devices have received considerable attention as superior flat panel displays since, for example, reduced power consumption and thickness and improved image quality can be achieved.

With the growing need for increasing the resolution of display devices, a technology in which vapor-deposited films including light-emitting films configured to emit red, green, and blue light are formed side-by-side for full-color display has been frequently employed in the field of organic EL display device manufacturing.

Methods other than those for forming vapor-deposited films including light-emitting films side-by-side using vapor deposition masks have also been proposed. For example, PTLs 1 and 2 disclose methods for forming vapor-deposited films including light-emitting films side-by-side using photolithography and dry etching steps.

PTL 3 discloses a laser ablation process in which an organic light-emitting film formed on an ITO thin film is selectively removed with laser light. PTL 4 discloses the formation of a patterned organic layer by light irradiation dry etching, in which an organic material layer is patterned by light irradiation using a resist pattern as a mask.

### CITATION LIST

### Patent Literature

PTL 1: Japanese Unexamined Patent Application Publication No. 2014-133727 (published on Jul. 24, 2014)

PTL 2: Japanese Unexamined Patent Application Publication No. 2014-44810 (published on Mar. 13, 2014)

PTL 3: Japanese Unexamined Patent Application Publication No. 2002-124380 (published on Apr. 26, 2002)

PTL 4: Japanese Unexamined Patent Application Publication No. 2000-36385 (published on Feb. 2, 2000)

### SUMMARY OF INVENTION

### Technical Problem

FIGS. 14(a) and 14(b) illustrate a common method, as disclosed in PTLs 1, 2, and 4 above, for forming vapor-deposited films including light-emitting films side-by-side using a resist formed by a photolithography step and a dry etching step in which the resist is used as a mask.

As shown in FIG. 14(a), conventionally, anodes 101, a hole injection film/hole transport film (HIL/HTL) 102, a blue light-emitting film (EML(B)) 103, a hole blocking film (HBL) 104, an electron transport film (ETL (sacrificial film)) 105, and a protective layer 106 are stacked in sequence on a substrate 100. A resist 107 is then formed only on the portions corresponding to blue pixels by a photolithography step.

As shown in FIG. 14(b), the films including the blue light-emitting film are then removed from the region where no resist 107 is formed by a dry etching step, for example, with ultraviolet radiation or oxygen plasma (O₂ plasma), using the resist 107 as a mask. Although not shown, films including a green light-emitting film are then formed over the entire surface in the same manner as in FIG. 14(a). The resist 107 formed on the blue pixels is then stripped to remove the films, including the green light-emitting film, formed on the resist 107. The films including the green light-emitting film remain only on the portion other than the blue pixels.

The resist 107 is then formed again only on the portions corresponding to the blue and green pixels by a photolithography step. The films including the green light-emitting film are then removed from the region where no resist 107 is formed with ultraviolet radiation or oxygen plasma (O₂ plasma) using the resist 107 as a mask. Thus, the films including the blue light-emitting film and the resist 107 are formed in the blue pixels, and the films including the green light-emitting film and the resist 107 are formed in the green pixels.

Films including a red light-emitting film are then formed over the entire surface in the same manner as in FIG. 14(a). The resist 107 formed on the blue and green pixels is then stripped to remove the films, including the red light-emitting film, formed on the resist 107. The films including the red light-emitting film remain only on the portion other than the blue and green pixels.

The resist 107 is then formed again only on the portions corresponding to the blue, green, and red pixels by a photolithography step. The films including the red light-emitting film are then removed from the region where no resist 107 is formed with ultraviolet radiation or oxygen plasma (O₂ plasma) using the resist 107 as a mask. Thus, the films including the blue light-emitting film and the resist 107 are formed in the blue pixels, the films including the green light-emitting film and the resist 107 are formed in the green pixels, and the films including the red light-emitting film and the resist 107 are formed in the red pixels. Finally, the resist 107 is stripped.

However, as described above, the conventional method for forming vapor-deposited films including light-emitting films side-by-side using photolithography and dry etching steps requires the resist 107 to be patterned three times and stripped three times and also requires films including light-emitting films of individual colors to be vapor-deposited for each color pixel. This results in a long manufacturing process and thus poor productivity. This method also requires films such as the protective layer 106 and the electron transport film (ETL (sacrificial film)) 105, which are formed of materials such as water-soluble materials and inorganic oxides, to be processed for each color pixel. This results in at least three times more loss in film processing.

Furthermore, the conventional method described above results in degraded light-emitting element characteristics because of the use of various stripping solutions and etchants, ultraviolet radiation, and oxygen plasma in the photolithography and etching steps. In particular, the use of a method in which the protective layer 106 is formed and contacted with a solvent affects elements with poor moisture resistance (decreases the efficiency and life thereof). On the other hand, the use of dry etching, for example, with ultraviolet radiation or oxygen plasma, results in color shifts (the effect of optical interference) due to changes in the thickness of the light-emitting elements, including the electron transport film (ETL (sacrificial film)) 105, and also results in degraded light-emitting element characteristics (emission efficiency and life).

In the laser ablation process disclosed in PTL 3, in which an organic light-emitting film is selectively removed with laser light, the layer below the organic light-emitting film to be removed by laser ablation is an ITO thin film. In this case, it is not necessary to consider damage to the ITO thin film by laser ablation, and therefore, no technique is employed to protect the layer below the organic light-emitting film. If an organic light-emitting film is stacked on another organic light-emitting film and the upper organic light-emitting film is removed by laser ablation, the lower organic light-emitting film would be damaged. Thus, the use of organic light-emitting films and laser ablation results in color shifts in light-emitting elements and degraded light-emitting element characteristics.

In view of the foregoing problems, an object of the present invention is to provide a display device and a method for manufacturing a display device with high productivity and with reduced color shift in light-emitting elements and reduced degradation in light-emitting element characteristics.

### Solution to Problem

To solve the foregoing problems, a display device according to the present invention includes first and second pixels configured to emit light with different peak wavelengths and a reflective electrode and a semitransparent reflective electrode provided in each pixel. A first light-emitting film is formed in the first pixel, and a second light-emitting film is formed in the second pixel. The remaining film percentage of a vapor-deposited film formed on the first light-emitting film after exposure to heat generated by irradiation with laser light is higher than the remaining film percentage of a vapor-deposited film formed on the second light-emitting film after exposure to heat generated by irradiation with laser light.

In this configuration, the remaining film percentage of the vapor-deposited film formed on the first light-emitting film after exposure to heat generated by irradiation with laser light is higher than the remaining film percentage of the vapor-deposited film formed on the second light-emitting film after exposure to heat generated by irradiation with laser light. Therefore, for example, if the second light-emitting film and the vapor-deposited film formed on the second light-emitting film are formed on the vapor-deposited film formed on the first light-emitting film and are removed by heating with laser light during the process of manufacturing the display device in order to achieve improved productivity, the effect of the heat on the first light-emitting film and the vapor-deposited film formed below the first light-emitting film can be reduced. Thus, a display device with high productivity and with reduced color shift in light-emitting elements and reduced degradation in light-emitting element characteristics can be achieved.

To solve the foregoing problems, a method for manufacturing a display device according to the present invention is a method for manufacturing a display device including first and second pixels provided on a substrate and configured to emit light with different peak wavelengths and a light-emitting film, a reflective electrode, and a semitransparent reflective electrode provided in each pixel. This method includes a conductive light-transmissive film formation step of forming a conductive light-transmissive film having a predetermined thickness in each pixel to adjust the distance between the light-emitting film and the reflective electrode such that light with the peak wavelength of the pixel is output from the semitransparent reflective electrode; a first vapor-deposited film formation step of forming a first vapor-deposited film including, of the light-emitting films, a first light-emitting film over an entire surface of the substrate including the first and second pixels; a step of removing the first vapor-deposited film including the first light-emitting film from a region other than the first pixel with laser light; a second vapor-deposited film formation step of forming a second vapor-deposited film including, of the light-emitting films, a second light-emitting film over the entire surface of the substrate including the first and second pixels; and a step of removing the second vapor-deposited film including the second light-emitting film from a region other than the second pixel with laser light. The remaining film percentage of a vapor-deposited film formed on the first light-emitting film in the first vapor-deposited film formation step after exposure to heat generated by irradiation with laser light is higher than the remaining film percentage of a vapor-deposited film formed on the second light-emitting film in the second vapor-deposited film formation step after exposure to heat generated by irradiation with laser light.

In this method, the remaining film percentage of the vapor-deposited film formed on the first light-emitting film in the first vapor-deposited film formation step after exposure to heat generated by irradiation with laser light is higher than the remaining film percentage of the vapor-deposited film formed on the second light-emitting film in the second vapor-deposited film formation step after exposure to heat generated by irradiation with laser light. Therefore, when any film on the vapor-deposited film formed on the first light-emitting film is removed by heating with laser light in the step of removing the second vapor-deposited film including the second light-emitting film from the region other than the second pixel with laser light, the effect of the heat on the first light-emitting film and the vapor-deposited film formed below the first light-emitting film can be reduced. Thus, a method for manufacturing a display device with reduced color shift in light-emitting elements and reduced degradation in light-emitting element characteristics can be achieved.

Thus, a method for manufacturing a display device with high productivity and with reduced color shift in light-emitting elements and reduced degradation in light-emitting element characteristics can be achieved.

### Advantageous Effects of Invention

According to one aspect of the present invention, a display device and a method for manufacturing a display device with high productivity and with reduced color shift in light-emitting elements and reduced degradation in light-emitting element characteristics can be achieved.

### BRIEF DESCRIPTION OF DRAWINGS

FIG. 1 schematically shows the configuration of an organic EL display device according to one embodiment of the present invention.

FIG. 2 illustrates a process of manufacturing the organic EL display device shown in FIG. 1.

FIGS. 3(a) to 3(d) show an example of a step of forming a vapor-deposited film in the B pixels of the organic EL display device shown in FIG. 1.

FIGS. 4(a) to 4(d) show an example of a step of forming a vapor-deposited film in the G and R pixels of the organic EL display device shown in FIG. 1 after the step shown in FIG. 3(d).

FIG. 5 schematically shows the configuration of an organic EL display device according to another embodiment of the present invention.

FIG. 6 illustrates a process of manufacturing the organic EL display device shown in FIG. 5.

FIGS. 7(a) to 7(d) show an example of a step of forming a vapor-deposited film in the G pixels of the organic EL display device shown in FIG. 5.

FIGS. 8(a) to 8(d) show an example of a step of forming a vapor-deposited film in the R and B pixels of the organic EL display device shown in FIG. 5 after the step shown in FIG. 7(d).

FIG. 9 schematically shows the configuration of an organic EL display device including color filters.

FIG. 10 schematically shows the configuration of an organic EL display device according to still another embodiment of the present invention.

FIG. 11 illustrates a process of manufacturing the organic EL display device shown in FIG. 10.

FIGS. 12(a) to 12(d) show an example of a step of forming a vapor-deposited film in the R pixels of the organic EL display device shown in FIG. 10.

FIGS. 13(a) to 13(d) show an example of a step of forming a vapor-deposited film in the G and B pixels of the organic EL display device shown in FIG. 10 after the step shown in FIG. 12(d).

FIGS. 14(a) and 14(b) illustrate a conventional method for forming vapor-deposited films including light-emitting films side-by-side using photolithography and dry etching steps.

### DESCRIPTION OF EMBODIMENTS

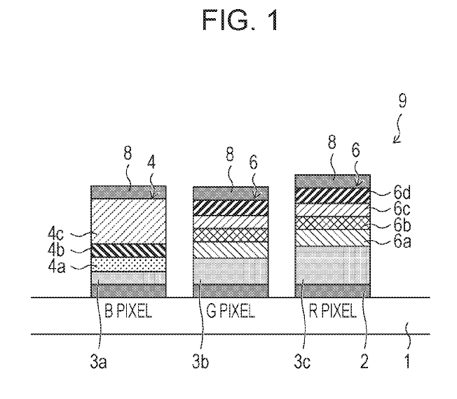

A description of embodiments of the present invention with reference to FIGS. 1 to 13 is as follows. For illustration purposes, the components having the same functions as those described in particular embodiments are denoted by the same reference signs, and a description thereof may be omitted.

### First Embodiment

A method for manufacturing an organic electroluminescence (EL) display device 9 and the configuration thereof will now be described with reference to FIGS. 1 to 4.

FIG. 1 schematically shows the configuration of the organic EL display device 9.

As shown, in each B pixel, an anode 2 (reflective electrode), an IZO film 3a, a hole injection film/hole transport film (HIL/HTL) 4a, a blue light-emitting film (EML(B)) 4b, an electron transport film (ETL) 4c, an electron injection film (not shown), and a cathode 8 (semitransparent reflective electrode) are stacked in sequence. The electron transport film (ETL) 4c is formed of the same material as an electron transport film (ETL) 6d in G and R pixels and is thicker than the electron transport film (ETL) 6d in the G and R pixels.

In each G pixel, an anode 2 (reflective electrode), an IZO film 3b, a hole injection film/hole transport film (HIL/HTL) 6a, a green light-emitting film (EML(G)) 6b, a red light-emitting film (EML(R)) 6c, an electron transport film (ETL) 6d, an electron injection film (not shown), and a cathode 8 (semitransparent reflective electrode) are stacked in sequence.

In each R pixel, an anode 2 (reflective electrode), an IZO film 3c, a hole injection film/hole transport film (HIL/HTL) 6a, a green light-emitting film (EML(G)) 6b, a red light-emitting film (EML(R)) 6c, an electron transport film (ETL) 6d, an electron injection film (not shown), and a cathode 8 (semitransparent reflective electrode) are stacked in sequence.

The thicknesses of the IZO films 3a, 3b, and 3c in the individual pixels can be determined as follows. The B, G, and R pixels emit light with different peak wavelengths (1). For example, the B pixels emit blue light with a peak wavelength (λ) of 450 nm, the G pixels emit green light with a peak wavelength (λ) of 530 nm, and the R pixels emit red light with a peak wavelength (λ) of 600 nm. The distance between the anode 2 (reflective electrode) and the light-emitting film in each pixel is preferably peak wavelength (λ)×¼×(2N−1) (where N is a natural number).

Thus, in each B pixel, the total thickness of the IZO film 3a and the hole injection film/hole transport film (HIL/HTL) 4a formed between the IZO film 3a and the blue light-emitting film (EML(B)) 4b may satisfy 450 nm×¼×(2N−1). Since the hole injection film/hole transport films (HIL/HTL) in the individual pixels have the same thickness in this embodiment, the IZO films 3a, 3b, and 3c in the individual pixels have different thicknesses. Similarly, in each G pixel, the total thickness of the IZO film 3b and the hole injection film/hole transport film (HIL/HTL) 6a formed between the IZO film 3b and the green light-emitting film (EML(G)) 6b may satisfy 530 nm×¼×(2N−1), and in each R pixel, the total thickness of the IZO film 3c and the hole injection film/hole transport film (HIL/HTL) 6a and the green light-emitting film (EML(G)) 6b formed between the IZO film 3c and the red light-emitting film (EML(R)) 6c may satisfy 600 nm×¼×(2N−1). In these expressions, N is the same natural number.

Although the case where the indium zinc oxide (IZO) films 3a, 3b, and 3c are used as transparent conductive films (transmissive films) is shown as an example in this embodiment, these films need not be used. For example, indium tin oxide (ITO) films may instead be used as transparent conductive films (transmissive films).

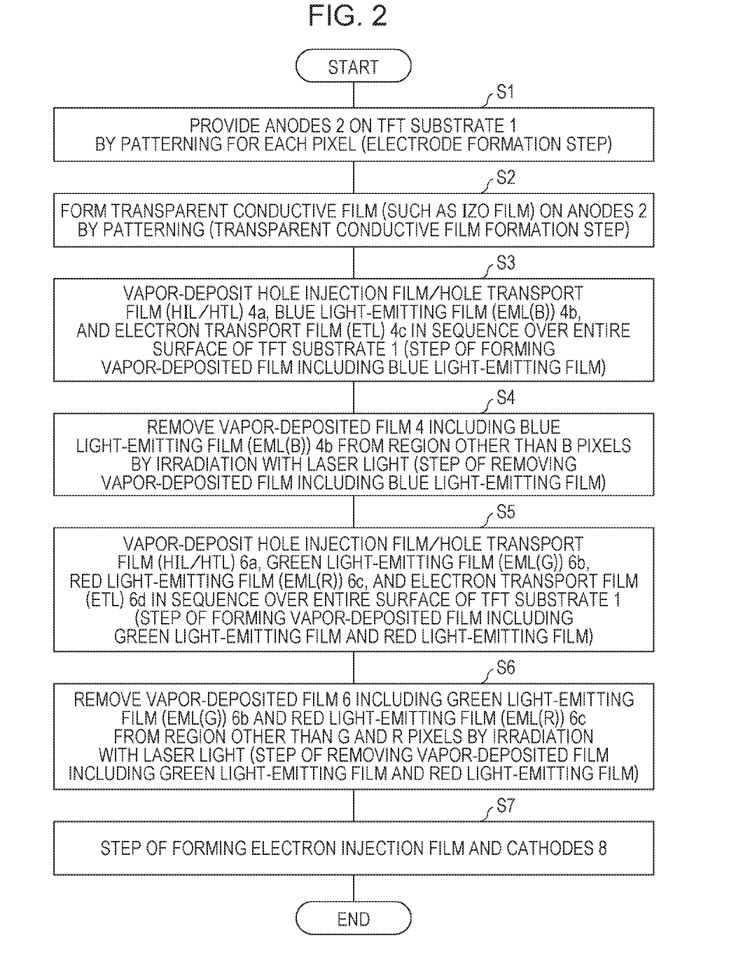

FIG. 2 illustrates a process of manufacturing the organic EL display device 9 shown in FIG. 1.

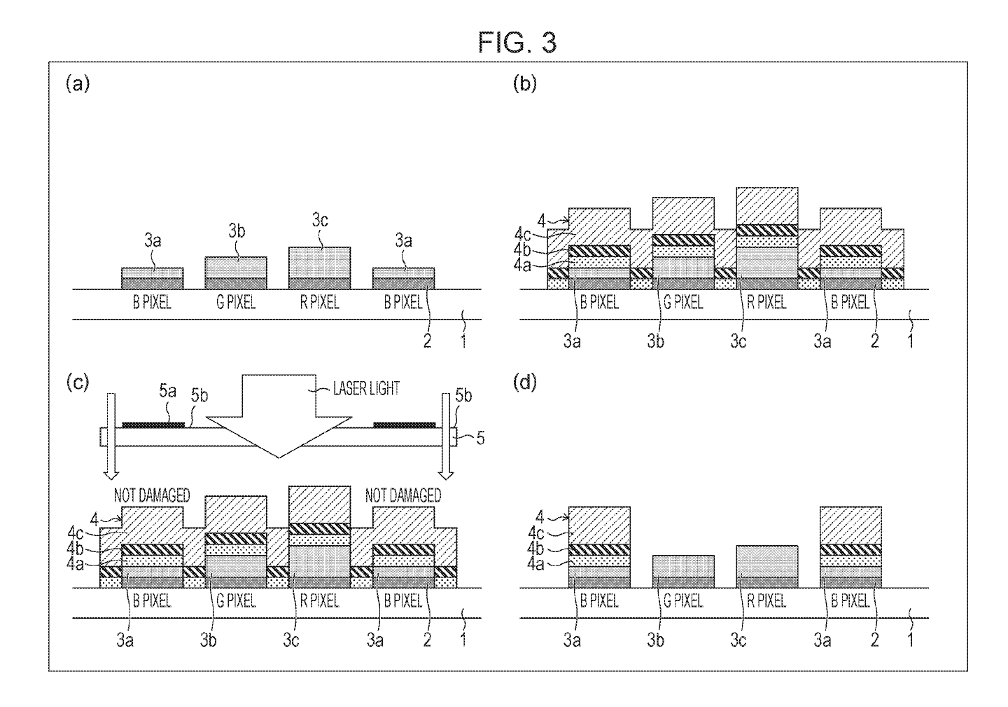

FIGS. 3(a) to 3(d) illustrate a step of forming a vapor-deposited film in the B pixels of the organic EL display device 9.

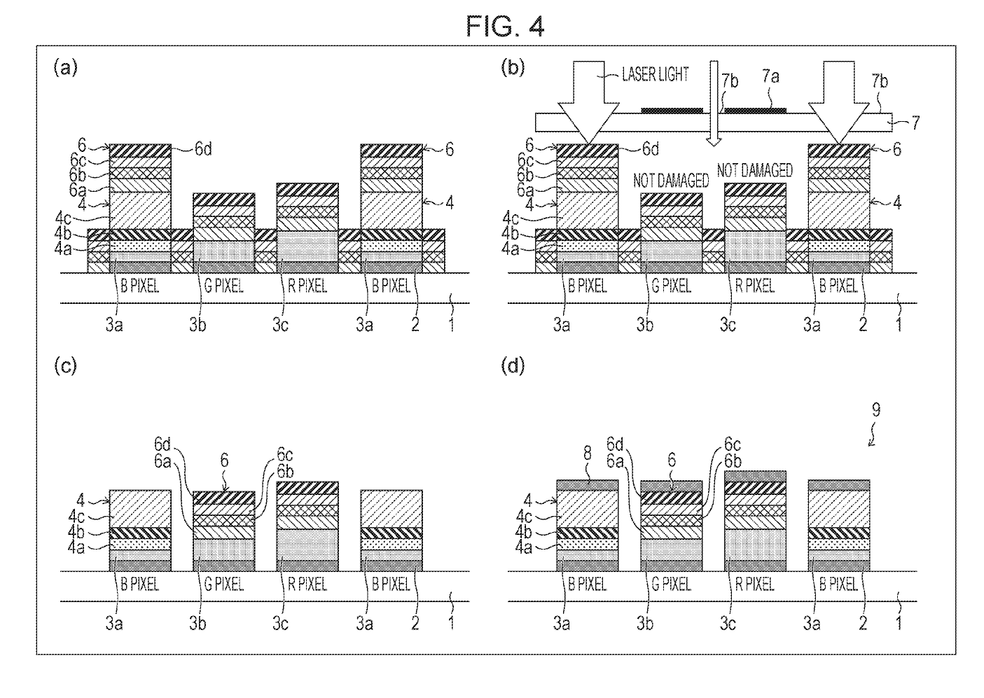

FIGS. 4(a) to 4(d) show an example of a step of forming a vapor-deposited film in the G and R pixels of the organic EL display device 9 after the step shown in FIG. 3(d).

An electrode formation step of providing the anodes 2 on a TFT substrate 1 by patterning for each pixel (S1 in FIG. 2) will be described first. Although not shown, a plurality of TFTs are provided on the TFT substrate 1 shown in FIG. 3(a). Although FIG. 3(a) shows only two B pixels, one G pixel, and one R pixel, a large number of B, G, and R pixels are provided depending on the resolution of the organic EL display device 9. One B pixel, one G pixel, and one R pixel that are adjacent to each other constitute one display unit for full-color display.

As shown in FIG. 3(a), the anodes 2 are provided on the TFT substrate 1 by patterning for each pixel (B, G, and R pixels) such that the anode 2 in each pixel is electrically connected to the drain electrode (or source electrode) of the TFT provided for that pixel. In this embodiment, the anodes 2 are formed of an Al film so that the anodes 2 serve as reflective electrodes, thereby providing a top-emission organic EL display device 9 configured to output light from the top side in the figure, i.e., from the side facing away from the TFT substrate 1. However, the anodes 2 need not be formed of an Al film, but may instead be formed of a Ag film. Alternatively, a bottom-emission organic EL display device 9 may be provided.

A transparent conductive film formation step of forming a transparent conductive film (also referred to as “conductive light-transmissive film”) on the anodes 2 by patterning for each pixel (S2 in FIG. 2) will then be described. The electrode formation step (S1 in FIG. 2) described above and the transparent conductive film formation step (S2 in FIG. 2) are collectively referred to as “anode formation step”.

As shown in FIG. 3(a), the indium zinc oxide (IZO) films 3a, 3b, and 3c, serving as transparent conductive films, are formed by patterning on the anodes 2, that is, such that the IZO films 3a, 3b, and 3c are electrically connected to the anodes 2. The anodes 2 and the IZO films 3a, 3b, and 3c can be formed by patterning, for example, using a resist and wet etching (or dry etching). In this embodiment, the anodes 2 and the IZO films 3a, 3b, and 3c serve as electrodes. The IZO films 3a, 3b, and 3c are formed so as to have a predetermined thickness for each pixel (B, G, and R pixels) by taking into account the effect of optical interference in each pixel (B, G, and R pixels).

Thus, the technology in which the IZO films 3a, 3b, and 3c or transmissive films are formed so as to have a predetermined thickness for each pixel (B, G, and R pixels) by taking into account the effect of optical interference is termed microcavity (microresonator) technology. Microcavity technology utilizes a microcavity (microresonator) effect to achieve improved emission chromaticity and efficiency.

The microcavity is the phenomenon in which emitted light undergoes multiple reflections and resonates between the anode and the cathode, thereby showing a sharp emission spectrum and an amplified emission intensity at the peak wavelength.

The microcavity effect can be achieved, for example, by optimizing the reflectance and thickness of the anode and the cathode and the thickness of the organic layer.

An example known method for introducing such a resonance structure, i.e., a microcavity structure, into organic EL elements is to vary the optical path length of the organic EL element in each pixel for each emission color. In this embodiment, the IZO films 3a, 3b, and 3c are formed so as to have a predetermined thickness for each pixel (B, G, and R pixels), thereby varying the optical path length of the organic EL elements.

A step of forming a vapor-deposited film including a blue light-emitting film (S3 in FIG. 2) will then be described. In this step, the hole injection film/hole transport film (HIL/HTL) 4a, the blue light-emitting film (EML(B)) 4b, and the electron transport film (ETL) 4c are vapor-deposited in sequence over the entire surface of the TFT substrate 1.

As shown in FIG. 3(b), a vapor-deposited film 4 including the blue light-emitting film (EML(B)) 4b is formed over the entire surface of the TFT substrate 1. As described in detail later, a thick electron transport film (ETL) 4c is formed by taking into account the subsequent steps.

A step of removing the vapor-deposited film including the blue light-emitting film (S4 in FIG. 2) will then be described. In this step, the vapor-deposited film 4 including the blue light-emitting film (EML(B)) 4b is removed from the region other than the B pixels by irradiation with laser light.

As shown in FIG. 3(c), the vapor-deposited film 4 including the blue light-emitting film (EML(B)) 4b is irradiated with laser light through a mask 5 including masking portions 5a and an opening 5b. The masking portions 5a of the mask 5 are located above the B pixel portions of the TFT substrate 1, i.e., above the regions where the IZO film 3a is stacked on the anodes 2, whereas the opening 5b of the mask 5 is located above the region other than the B pixel portions of the TFT substrate 1. Thus, the vapor-deposited film 4 including the blue light-emitting film (EML(B)) 4b is irradiated with laser light over the entire region other than the B pixel portions of the TFT substrate 1. Since the vapor-deposited film 4 including the blue light-emitting film (EML(B)) 4b is formed of an organic material and the IZO films 3b and 3c are formed of an inorganic material, the vapor-deposited film 4 including the blue light-emitting film (EML(B)) 4b is selectively removed from the IZO films 3b and 3c and from the region between the individual pixels by heating with laser light. Thus, as shown in FIG. 3(d), the vapor-deposited film 4 including the blue light-emitting film (EML(B)) 4b can be patterned so as to remain only in the B pixels.

As shown in FIG. 3(c), since the masking portions 5a of the mask 5 are located above the B pixels of the TFT substrate 1i, the vapor-deposited film 4 including the blue light-emitting film (EML(B)) 4b in the B pixels is not irradiated with laser light and is thus not damaged by laser light.

The step of removing the vapor-deposited film including the blue light-emitting film is preferably performed in a vacuum atmosphere or an atmosphere having low water and oxygen contents, for example, less than 10 ppm. Although the case where irradiation with laser light is performed through the mask 5 is shown as an example in this embodiment, irradiation with laser light can be performed without a mask if the laser light used for irradiation has a sufficiently small irradiation width for patterning.

The laser light used in the step of removing the vapor-deposited film including the blue light-emitting film is intended to remove, by heating with the laser light, a vapor-deposited film, including a light-emitting film, below which there is no vapor-deposited film, including a light-emitting film, that needs to be protected. It is therefore not necessary to give much consideration to reduce the conduction of heat generated by the laser light to other films. Thus, it is not necessary to use pulsed laser light with an extremely short duration (e.g., an extremely short duration of the order of femtoseconds (10⁻¹⁵) to picoseconds (10⁻¹²)), as described later. For example, pulsed laser light with a relatively long duration can be used instead. Although this embodiment uses pulsed laser light with a relatively long duration in the step of removing the vapor-deposited film including the blue light-emitting film in order to shorten the process time, this laser light need not be used.

As described above, this embodiment uses heating with laser light for the patterning of vapor-deposited films including light-emitting films. This eliminates the need to form and strip resist films as in conventional methods.

A step of forming a vapor-deposited film including a green light-emitting film and a red light-emitting film (S5 in FIG. 2) will then be described. In this step, the hole injection film/hole transport film (HIL/HTL) 6a, the green light-emitting film (EML(G)) 6b, the red light-emitting film (EML(R)) 6c, and the electron transport film (ETL) 6d are vapor-deposited in sequence over the entire surface of the TFT substrate 1.

As shown in FIG. 4(a), a vapor-deposited film 6 including the green light-emitting film (EML(G)) 6b and the red light-emitting film (EML(R)) 6c is formed over the entire surface of the TFT substrate 1.

As described above, the stack of the green light-emitting film (EML(G)) 6b and the red light-emitting film (EML(R)) 6c is formed as common layers in the G and R pixels. In this case, phosphorescent materials are used as dopants, and a common host material can be used. This provides the advantage of requiring only the dopant to be changed in the step of forming the vapor-deposited film including the green light-emitting film and the red light-emitting film.

In this embodiment, the vapor-deposited film 6 including the green light-emitting film (EML(G)) 6b and the red light-emitting film 6c is vapor-deposited such that the lower layer is the green light-emitting film (EML(G)) 6b and the upper layer is the red light-emitting film (EML(R)) 6c from the standpoint of carrier characteristics, that is, electron-hole recombination balance. Alternatively, the vapor-deposited film 6 including the green light-emitting film (EML(G)) 6b and the red light-emitting film (EML(R)) 6c may be vapor-deposited such that the lower layer is the red light-emitting film (EML(R)) 6c and the upper layer is the green light-emitting film (EML(G)) 6b. In this case, it should only be noted that the thicknesses of the IZO films 3b and 3c are changed.

A step of removing the vapor-deposited film including the green light-emitting film and the red light-emitting film (S6 in FIG. 2) will then be described. In this step, the vapor-deposited film 6 including the green light-emitting film (EML(G)) 6b and the red light-emitting film (EML(R)) 6c is removed from the region other than the G and R pixels by irradiation with laser light.

As shown in FIG. 4(b), the vapor-deposited film 6 including the green light-emitting film (EML(G)) 6b and the red light-emitting film (EML(R)) 6c is irradiated with laser light through a mask 7 including masking portions 7a and an opening 7b. The masking portions 7a of the mask 7 are located above the G and R pixel portions of the TFT substrate 1, i.e., above the regions where the IZO film 3b is stacked on the anodes 2 and the regions where the IZO film 3c is stacked on the anodes 2, whereas the opening 7b of the mask 7 is located above the region other than the G and R pixel portions of the TFT substrate 1. Thus, the vapor-deposited film 6 including the green light-emitting film (EML(G)) 6b and the red light-emitting film (EML(R)) 6c is irradiated with laser light over the entire region other than the G and R pixel portions of the TFT substrate 1. Since the vapor-deposited film 6 including the green light-emitting film (EML(G)) 6b and the red light-emitting film (EML(R)) 6c is formed of an organic material, the vapor-deposited film 6 including the green light-emitting film (EML(G)) 6b and the red light-emitting film (EML(R)) 6c is selectively removed from the B pixel portions of the TFT substrate 1 and from the region between the individual pixels by heating with laser light. Thus, as shown in FIG. 4(c), the vapor-deposited film 4 including the blue light-emitting film (EML(B)) 4b can be patterned so as to remain on the B pixel portions of the TFT substrate 1, whereas the vapor-deposited film 6 including the green light-emitting film (EML(G)) 6b and the red light-emitting film (EML(R)) 6c can be patterned so as to remain on the G and R pixel portions of the TFT substrate 1.

As shown in FIG. 4(b), since the masking portions 7a of the mask 7 are located above the G and R pixels of the TFT substrate 1, the vapor-deposited film 6 including the green light-emitting film (EML(G)) 6b and the red light-emitting film (EML(R)) 6c in the G and R pixels is not irradiated with laser light and is thus not damaged by laser light.

The vapor-deposited film 4, including the blue light-emitting film (EML(B)) 4b, formed on the B pixel portions of the TFT substrate 1 includes a thick electron transport film (ETL) 4c formed on the assumption that the laser light used in the step of removing the vapor-deposited film including the green light-emitting film and the red light-emitting film is the pulsed laser light with a relatively long duration used in the step of removing the vapor-deposited film including the blue light-emitting film. This is intended to minimize the effect of heat generated by irradiation with laser light on the blue light-emitting film (EML(B)) 4b and the hole injection film/hole transport film (HIL/HTL) 4a during the step of removing the vapor-deposited film 6, including the green light-emitting film (EML(G)) 6b and the red light-emitting film (EML(R)) 6c, formed on the vapor-deposited film 4 including the blue light-emitting film (EML(B)) 4b in the B pixels. The electron transport film (ETL) 4c in the B pixels also tends to have variations in thickness (e.g., damage during pattering) because of the process characteristics, i.e., the use of heat generated by irradiation with laser light for patterning. Thus, it is preferred to form a thick electron transport film (ETL) 4c in the B pixels so that less color change occurs. As the electron transport film (ETL) 4c becomes thicker, the entire vapor-deposited film 4 including the blue light-emitting film (EML(B)) 4b becomes thicker.

If the laser light used in the step of removing the vapor-deposited film including the green light-emitting film and the red light-emitting film is pulsed laser light with an extremely short duration (e.g., an extremely short duration of the order of femtoseconds (10⁻¹⁵) to picoseconds (10⁻¹²)), the conduction of heat generated by the laser light to other films can be reduced. This allows a thin electron transport film (ETL) 4c to be formed as compared to the use of pulsed laser light with a relatively long duration as described above. The step of removing the vapor-deposited film including the green light-emitting film and the red light-emitting film is preferably performed in a vacuum atmosphere or an atmosphere containing less than 10 ppm water and oxygen.

Finally, a step of forming the electron injection film and the cathodes 8 (S7 in FIG. 2) will be described.

As shown in FIG. 4(d), the electron injection film (not shown) and the cathodes 8 are formed in sequence over the entire surface of the TFT substrate 1 and are then patterned. After encapsulation for each pixel or over the entire TFT substrate 1, the organic EL display device 9 is completed, which has a plurality of organic EL elements (light-emitting elements) on the TFT substrate 1. Although this embodiment uses LiF as the electron injection film, this material need not be used. Although this embodiment uses a stack of thin Ag and ITO films as the cathodes 8 (semitransparent reflective electrodes), these films need not be used.

Drive circuitry for driving the plurality of organic EL elements may be provided on or externally attached to the TFT substrate 1.

In this embodiment, the electron transport film (ETL) 4c of the vapor-deposited film 4 formed in the B pixels is thicker than the electron transport film (ETL) 6d formed in the G and R pixels so that, when patterning is performed twice as described above, laser damage to the vapor-deposited film 4 remaining in the B pixels after the first patterning (the step of removing the vapor-deposited film including the blue light-emitting film) is reduced or avoided during the second patterning (the step of removing the vapor-deposited film including the green light-emitting film and the red light-emitting film). However, this method need not be used to reduce or avoid laser damage to the vapor-deposited film 4 in the B pixels during the step of removing the vapor-deposited film including the green light-emitting film and the red light-emitting film.

For example, at least a portion of the electron transport film (ETL) 4c in the B pixels shown in FIG. 1 may contain at least one of an inorganic material, an inorganic metal oxide, and a crystalline organic material in a larger amount than the electron transport film (ETL) 6d in the G and R pixels.

If the laser light used in the step of removing the vapor-deposited film including the green light-emitting film and the red light-emitting film is pulsed laser light with an extremely short duration (e.g., an extremely short duration of the order of femtoseconds (10⁻¹⁵) to picoseconds (10⁻¹²)), the conduction of heat generated by the laser light to other films can be reduced. This allows the amount of at least one of an inorganic material, an inorganic metal oxide, and a crystalline organic material present in the electron transport film (ETL) 4c in the B pixels to be reduced as compared to the use of pulsed laser light with a relatively long duration as described above.

If the electron transport film (ETL) 4c in the B pixels contains a large amount of an inorganic material, an inorganic metal oxide (e.g., an inorganic metal oxide with a low work function (an alkali metal oxide, an alkaline earth metal oxide, or a composite oxide containing such an oxide with a work function of about −3 eV), or a crystalline organic material (e.g., an organic material, such as a phenanthroline-based material, that recrystallizes readily due to its low glass transition), the remaining film percentage of the electron transport film (ETL) 4c after exposure to heat generated by irradiation with laser light and the heat resistance thereof can be improved. This reduces the effect of heat generated by irradiation with laser light on the lower layers. The crystalline organic material is an organic material that has high film density due to crystallization. For example, if an organic material with a low glass transition point (e.g., a glass transition point of lower than 120° C.) is used, the organic material with a low glass transition point crystallizes with heat generated by irradiation with laser light during the step of removing the vapor-deposited film including the green light-emitting film and the red light-emitting film shown in FIG. 4(b). During this process, heat absorption occurs, thus reducing the effect of heat generated by irradiation with laser light on the lower layers.

Although not shown, the thickness of the electron transport film (ETL) 4c formed in the B pixels may be smaller than or equal to the thickness of the electron transport film (ETL) 6d formed in the G and R pixels, and the electron transport film (ETL) 4c in the B pixels may contain at least one of an inorganic material, an inorganic metal oxide, and a crystalline organic material in a larger amount than the electron transport film (ETL) 6d in the G and R pixels.

Thus, it is desirable that the electron transport film (ETL) 4c in the B pixels be resistant to etching by irradiation with laser light or have a sufficient thickness to protect the blue light-emitting film (EML(B)) 4b and the hole injection film/hole transport film (HIL/HTL) 4a after being etched. In other words, it is desirable that the remaining film percentage of the electron transport film (ETL) 4c in the B pixels after irradiation with laser light be high enough to ensure a predetermined thickness or more.

If it is assumed that the electron transport films (ETL) 4c and 6d are formed of the same material and are both irradiated with the same laser light, the electron transport films (ETL) 4c and 6d are removed by the same thickness with heat generated by irradiation with laser light. Thus, a larger film thickness results in a higher remaining film percentage after exposure to heat generated by irradiation with laser light.

As described above, if the electron transport film (ETL) 4c in the B pixels contains a large amount of an inorganic material, an inorganic metal oxide, or a crystalline organic material, the remaining film percentage of the electron transport film (ETL) 4c in the B pixels after exposure to heat generated by irradiation with laser light is higher than the remaining film percentage of the electron transport film (ETL) 6d in the G and R pixels after exposure to heat generated by irradiation with the laser light.

Thus, it is desirable that the remaining film percentage of the electron transport film (ETL) 4c in the B pixels after exposure to heat generated by irradiation with laser light be higher than the remaining film percentage of the electron transport film (ETL) 6d in the G and R pixels after exposure to heat generated by irradiation with the laser light.

The remaining film percentage after exposure to heat generated by irradiation with laser light is defined as follows: (film thickness after irradiation with laser light for predetermined period of time)/(initial film thickness before irradiation with laser light)×100.

Although organic EL light-emitting elements including an anode (reflective electrode), an IZO film, a hole injection film/hole transport film (HIL/HTL), one or two light-emitting films (EML), an electron transport film (ETL), an electron injection film, and a cathode (semitransparent reflective electrode) have been described as an example in this embodiment, these films need not be used. The organic EL light-emitting elements may further include, for example, an electron injection layer and a carrier blocking film such as a hole blocking film or electron blocking film.

The difference between the organic EL display device 9 shown in FIG. 1 and an organic EL display device manufactured by a conventional common side-by-side method in which films above light-emitting layers, such as an electron transport film (ETL), are vapor-deposited as common layers in each pixel is as follows. In an organic EL display device manufactured by a conventional common side-by-side method in which films above light-emitting layers, such as an electron transport film (ETL), are vapor-deposited as common layers in each pixel, there is no difference in the thickness and material of the electron transport film (ETL) in each pixel as described above.

Although patterning by dry etching using a conventional side-by-side method in which a mask or resist is used offers great flexibility in setting the thickness of the electron transport film (ETL) vapor-deposited as a common layer, this method does not provide a structure in which a green light-emitting film (EML(G)) and a red light-emitting film (EML(R)) are formed as common layers in G and R pixels.

In this embodiment, the stack of the green light-emitting film (EML(G)) 6b and the red light-emitting film (EML(R)) 6c is formed as common layers in the G and R pixels. However, the stack of the green light-emitting film and the red light-emitting film need not be formed in the G and R pixels as long as the remaining film percentage of the electron transport film formed on the light-emitting film in one pixel, for example, the B pixels, after exposure to heat generated by irradiation with laser light is higher than the remaining film percentage of the electron transport film formed on the light-emitting film in other pixels, for example, the G and R pixels, after exposure to heat generated by irradiation with laser light. Alternatively, it is possible to form only the green light-emitting film in the G pixels and only the red light-emitting film in the R pixels.

### Second Embodiment

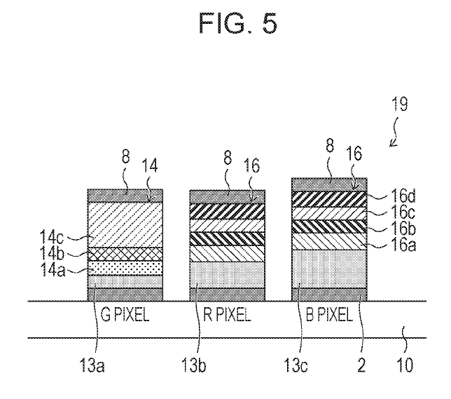

A second embodiment of the present invention will now be described with reference to FIGS. 5 to 9. This embodiment differs from the first embodiment in that a vapor-deposited film 14 including a green light-emitting film (EML(G)) 14b is formed in the G pixels before a vapor-deposited film 16 including a blue light-emitting film (EML(B)) 16b and a red light-emitting film (EML(R)) 16c is formed in the R and B pixels. Other details are as described in the first embodiment. For illustration purposes, the members having the same functions as those shown in the figures for the first embodiment are denoted by the same reference signs, and a description thereof is omitted.

FIG. 5 schematically shows the configuration of an organic EL display device 19.

As shown, in each G pixel, an anode 2 (reflective electrode), an IZO film 13a, a hole injection film/hole transport film (HIL/HTL) 14a, a green light-emitting film (EML(G)) 14b, an electron transport film (ETL) 14c, an electron injection film (not shown), and a cathode 8 (semitransparent reflective electrode) are stacked in sequence. The electron transport film (ETL) 14c is formed of the same material as an electron transport film (ETL) 16d in the R and B pixels and is thicker than the electron transport film (ETL) 16d.

In each R pixel, an anode 2 (reflective electrode), an IZO film 13b, a hole injection film/hole transport film (HIL/HTL) 16a, a blue light-emitting film (EML(B)) 16b, a red light-emitting film (EML(R)) 16c, an electron transport film (ETL) 16d, an electron injection film (not shown), and a cathode 8 (semitransparent reflective electrode) are stacked in sequence.

In each B pixel, an anode 2 (reflective electrode), an IZO film 13c, a hole injection film/hole transport film (HIL/HTL) 16a, a blue light-emitting film (EML(B)) 16b, a red light-emitting film (EML(R)) 16c, an electron transport film (ETL) 16d, an electron injection film (not shown), and a cathode 8 (semitransparent reflective electrode) are stacked in sequence.

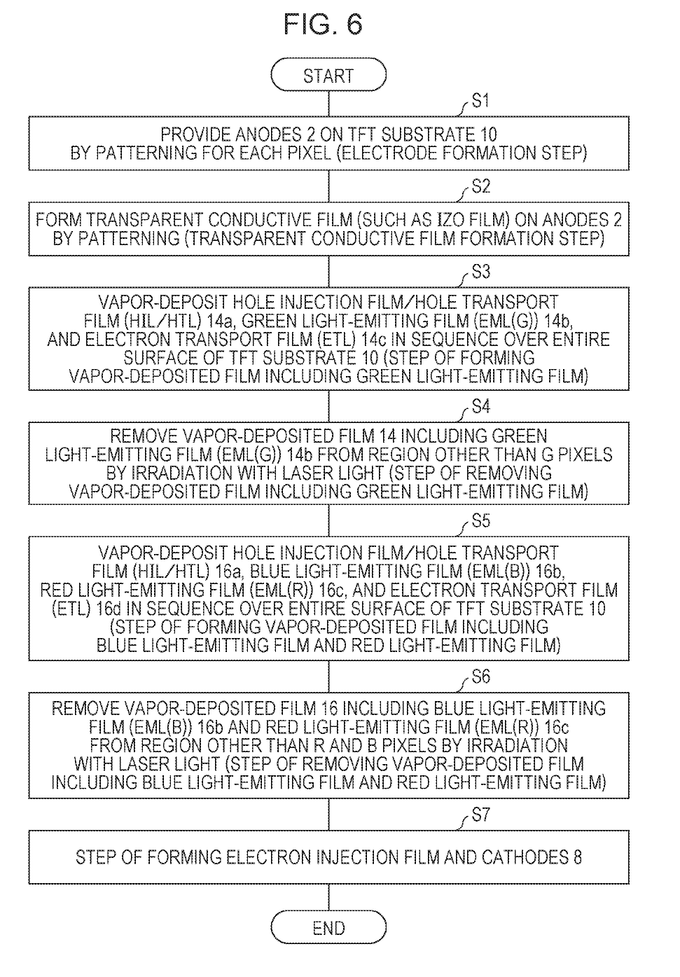

FIG. 6 illustrates a process of manufacturing the organic EL display device 19 shown in FIG. 5.

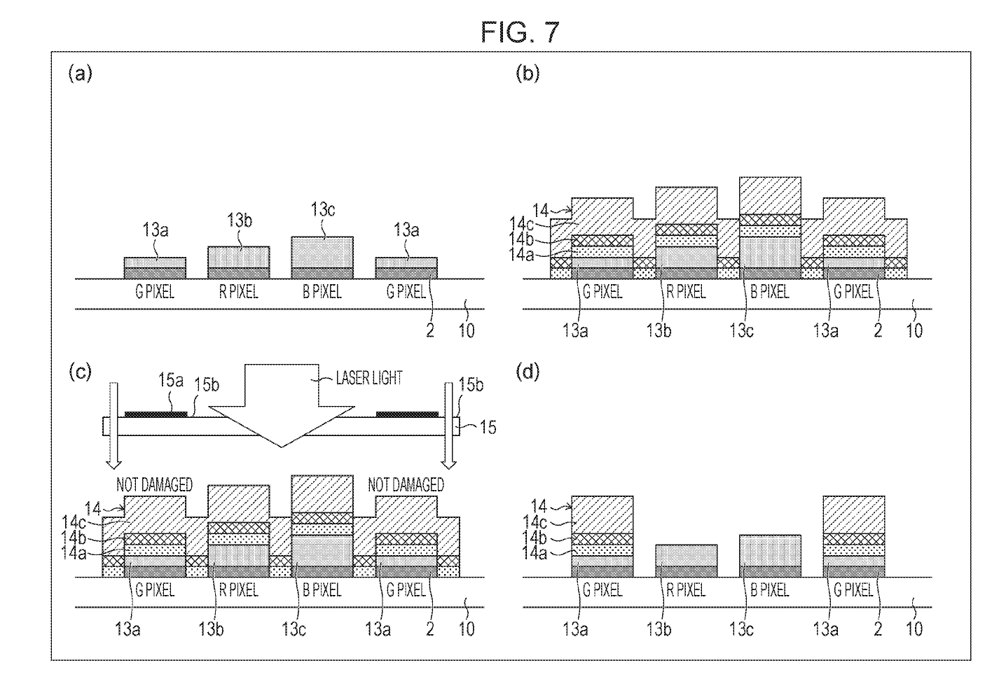

FIGS. 7(a) to 7(d) illustrate a step of forming a vapor-deposited film in the G pixels of the organic EL display device 19.

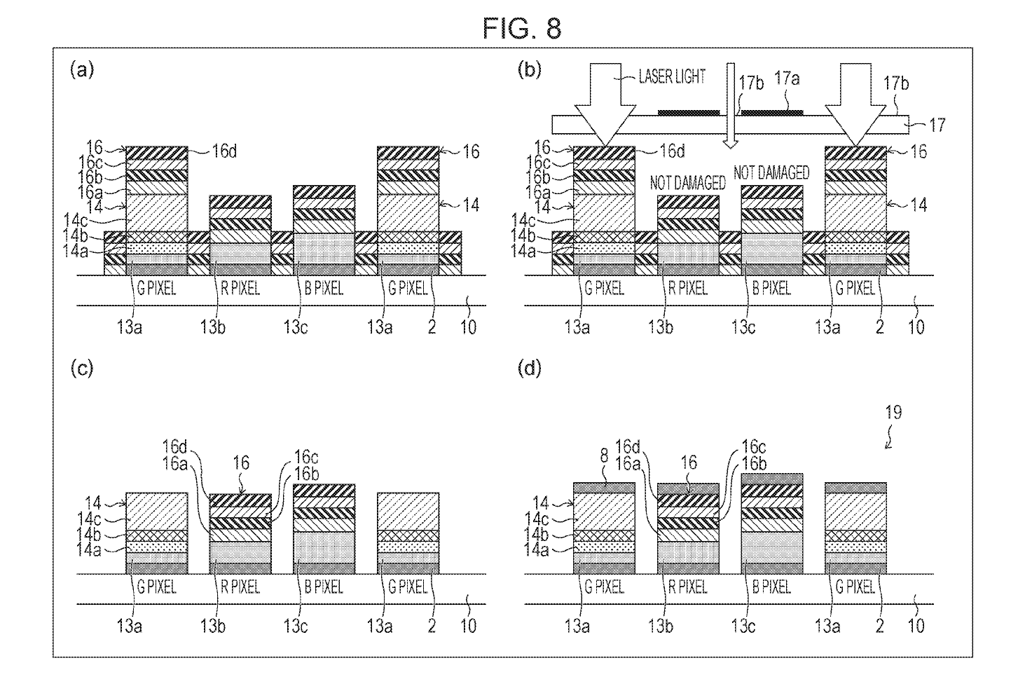

FIGS. 8(a) to 8(d) show an example of a step of forming a vapor-deposited film in the R and B pixels of the organic EL display device 19 after the step shown in FIG. 7(d).

An electrode formation step of providing the anodes 2 on a TFT substrate 10 by patterning for each pixel (S1 in FIG. 6) will be described first. As shown in FIG. 7(a), the anodes 2 are provided on the TFT substrate 10 by patterning for each pixel (G, R, and B pixels) such that the anode 2 in each pixel is electrically connected to the drain electrode (or source electrode) of the TFT provided for that pixel.

A transparent conductive film formation step of forming a transparent conductive film (also referred to as “conductive light-transmissive film”) on the anodes 2 by patterning for each pixel (S2 in FIG. 6) will then be described. The electrode formation step (S1 in FIG. 6) described above and the transparent conductive film formation step (S2 in FIG. 6) are collectively referred to as “anode formation step”.

As shown in FIG. 7(a), the indium zinc oxide (IZO) films 13a, 13b, and 13c, serving as transparent conductive films, are formed by patterning on the anodes 2, that is, such that the IZO films 13a, 13b, and 13c are electrically connected to the anodes 2. The IZO films 13a, 13b, and 13c are formed so as to have a predetermined thickness for each pixel (G, R, and B pixels) by taking into account the effect of optical interference in each pixel (G, R, and B pixels).

A step of forming a vapor-deposited film including a green light-emitting film (S3 in FIG. 6) will then be described. In this step, the hole injection film/hole transport film (HIL/HTL) 14a, the green light-emitting film (EML(G)) 14b, and the electron transport film (ETL) 14c are vapor-deposited in sequence over the entire surface of the TFT substrate 10.

As shown in FIG. 7(b), the vapor-deposited film 14 including the green light-emitting film (EML(G)) 14b is formed over the entire surface of the TFT substrate 10. As described in detail later, a thick electron transport film (ETL) 4c is formed by taking into account the subsequent steps.

A step of removing the vapor-deposited film including the green light-emitting film (S4 in FIG. 6) will then be described. In this step, the vapor-deposited film 14 including the green light-emitting film (EML(G)) 14b is removed from the region other than the G pixels by irradiation with laser light.

As shown in FIG. 7(c), the vapor-deposited film 14 including the green light-emitting film (EML(G)) 14b is irradiated with laser light through a mask 15 including masking portions 15a and an opening 15b. The masking portions 15a of the mask 15 are located above the G pixel portions of the TFT substrate 10, i.e., above the regions where the IZO film 13a is stacked on the anodes 2, whereas the opening 15b of the mask 15 is located above the region other than the G pixel portions of the TFT substrate 10. Thus, the vapor-deposited film 14 including the green light-emitting film (EML(G)) 14b is irradiated with laser light over the entire region other than the G pixel portions of the TFT substrate 10. Since the vapor-deposited film 14 including the green light-emitting film (EML(G)) 14b is formed of an organic material and the IZO films 13b and 13c are formed of an inorganic material, the vapor-deposited film 14 including the green light-emitting film (EML(G)) 14b is selectively removed from the IZO films 13b and 13c and from the region between the individual pixels by heating with laser light. Thus, as shown in FIG. 7(d), the vapor-deposited film 14 including the green light-emitting film (EML(G)) 14b can be patterned so as to remain only in the G pixels.

As shown in FIG. 7(c), since the masking portions 15a of the mask 15 are located above the G pixels of the TFT substrate 10, the vapor-deposited film 14 including the green light-emitting film (EML(G)) 14b in the G pixels is not irradiated with laser light and is thus not damaged by laser light.

The step of removing the vapor-deposited film including the green light-emitting film is preferably performed in a vacuum atmosphere or an atmosphere having low water and oxygen contents, for example, less than 10 ppm.

As described above, this embodiment uses heating with laser light for patterning. This eliminates the need to form and strip resist films as in conventional methods.

The laser light used in the step of removing the vapor-deposited film including the green light-emitting film is intended to remove, by heating with the laser light, a vapor-deposited film, including a light-emitting film, below which there is no vapor-deposited film, including a light-emitting film, that needs to be protected. It is therefore not necessary to give much consideration to reduce the conduction of heat generated by the laser light to other films. Thus, it is not necessary to use pulsed laser light with an extremely short duration (e.g., an extremely short duration of the order of femtoseconds (10⁻¹⁵) to picoseconds (10⁻¹²)). For example, pulsed laser light with a relatively long duration can be used instead. Although this embodiment uses pulsed laser light with a relatively long duration in the step of removing the vapor-deposited film including the green light-emitting film in order to shorten the process time, this laser light need not be used.

A step of forming a vapor-deposited film including a blue light-emitting film and a red light-emitting film (S5 in FIG. 6) will then be described. In this step, the hole injection film/hole transport film (HIL/HTL) 16a, the blue light-emitting film (EML(B)) 16b, the red light-emitting film (EML(R)) 16c, and the electron transport film (ETL) 16d are vapor-deposited in sequence over the entire surface of the TFT substrate 10.

As shown in FIG. 8(a), the vapor-deposited film 16 including the blue light-emitting film (EML(B)) 16b and the red light-emitting film (EML(R)) 16c is formed over the entire surface of the TFT substrate 10.

As described above, the blue light-emitting film (EML(B)) 16b and the red light-emitting film (EML(R)) 16c are formed as common layers in the R and B pixels.

In this embodiment, the vapor-deposited film 16 including the blue light-emitting film (EML(B)) 16b and the red light-emitting film (EML(R)) 16c is vapor-deposited such that the lower layer is the blue light-emitting film (EML(B)) 16b and the upper layer is the red light-emitting film (EML(R)) 16c from the standpoint of carrier characteristics, that is, electron-hole recombination balance. Alternatively, the vapor-deposited film 16 including the blue light-emitting film (EML(B)) 16b and the red light-emitting film (EML(R)) 16c may be vapor-deposited such that the lower layer is the red light-emitting film (EML(R)) 16c and the upper layer is the blue light-emitting film (EML(B)) 16b. In this case, it should only be noted that the thicknesses of the IZO films 13b and 13c are changed.

A step of removing the vapor-deposited film including the blue light-emitting film and the red light-emitting film (S6 in FIG. 6) will then be described. In this step, the vapor-deposited film 16 including the blue light-emitting film (EML(B)) 16b and the red light-emitting film (EML(R)) 16c is removed from the region other than the R and B pixels by irradiation with laser light.

As shown in FIG. 8(b), the vapor-deposited film 16 including the blue light-emitting film (EML(B)) 16b and the red light-emitting film (EML(R)) 16c is irradiated with laser light through a mask 17 including masking portions 17a and an opening 17b. The masking portions 17a of the mask 17 are located above the R and B pixel portions of the TFT substrate 10, i.e., above the regions where the IZO film 13b is stacked on the anodes 2 and the regions where the IZO film 13c is stacked on the anodes 2, whereas the opening 17b of the mask 17 is located above the region other than the R and B pixel portions of the TFT substrate 10. Thus, the vapor-deposited film 16 including the blue light-emitting film (EML(B)) 16b and the red light-emitting film (EML(R)) 16c is irradiated with laser light over the entire region other than the R and B pixel portions of the TFT substrate 10. Since the vapor-deposited film 16 including the blue light-emitting film (EML(B)) 16b and the red light-emitting film (EML(R)) 16c is formed of an organic material, the vapor-deposited film 16 including the blue light-emitting film (EML(B)) 16b and the red light-emitting film (EML(R)) 16c is selectively removed from the G pixel portions of the TFT substrate 10 and from the region between the individual pixels by heating with laser light. Thus, as shown in FIG. 8(c), the vapor-deposited film 14 including the green light-emitting film (EML(G)) 14b can be patterned so as to remain on the G pixel portions of the TFT substrate 10, whereas the vapor-deposited film 16 including the blue light-emitting film (EML(B)) 16b and the red light-emitting film (EML(R)) 16c can be patterned so as to remain on the R and B pixel portions of the TFT substrate 10.

As shown in FIG. 8(b), since the masking portions 17a of the mask 17 are located above the R and B pixels of the TFT substrate 10, the vapor-deposited film 16 including the blue light-emitting film (EML(B)) 16b and the red light-emitting film (EML(R)) 16c in the R and B pixels is not irradiated with laser light and is thus not damaged by laser light.

The vapor-deposited film 14, including the green light-emitting film (EML(G)) 14b, formed on the G pixel portions of the TFT substrate 10 includes a thick electron transport film (ETL) 14c formed on the assumption that the laser light used in the step of removing the vapor-deposited film including the blue light-emitting film and the red light-emitting film is the pulsed laser light with a relatively long duration used in the step of removing the vapor-deposited film including the green light-emitting film. This is intended to minimize the effect of heat generated by irradiation with laser light on the green light-emitting film (EML(G)) 14b and the hole injection film/hole transport film (HIL/HTL) 14a during the step of removing the vapor-deposited film 16, including the blue light-emitting film (EML(B)) 16b and the red light-emitting film (EML(R)) 16c, formed on the vapor-deposited film 14 including the green light-emitting film (EML(G)) 14b in the G pixels. The electron transport film (ETL) 14c in the G pixels also tends to have variations in thickness (e.g., damage during pattering) because of the process characteristics, i.e., the use of heat generated by irradiation with laser light for patterning. Thus, it is preferred to form a thick electron transport film (ETL) 14c in the G pixels so that less color change occurs. As the electron transport film (ETL) 14c becomes thicker, the entire vapor-deposited film 14 including the green light-emitting film (EML(G)) 14b becomes thicker.

In this embodiment, the electron transport film (ETL) 14c in the G pixels is formed of the same material as the electron transport film (ETL) 16d in the R and B pixels and is thicker than the electron transport film (ETL) 16d in the R and B pixels so that the remaining film percentage of the electron transport film (ETL) 14c in the G pixels after exposure to heat generated by irradiation with laser light is higher than the remaining film percentage of the electron transport film (ETL) 16d in the R and B pixels after exposure to heat generated by irradiation with the laser light.

If the laser light used in the step of removing the vapor-deposited film including the blue light-emitting film and the red light-emitting film is pulsed laser light with an extremely short duration (e.g., an extremely short duration of the order of femtoseconds (10⁻¹⁵) to picoseconds (10⁻¹²)), the conduction of heat generated by the laser light to other films can be reduced. This allows a thin electron transport film (ETL) 14c to be formed as compared to the use of pulsed laser light with a relatively long duration as described above. The step of removing the vapor-deposited film including the blue light-emitting film and the red light-emitting film is preferably performed in a vacuum atmosphere or an atmosphere containing less than 10 ppm water and oxygen.

Finally, a step of forming the electron injection film and the cathodes 8 (S7 in FIG. 6) will be described.

As shown in FIG. 8(d), the electron injection film (not shown) and the cathodes 8 are formed in sequence over the entire surface of the TFT substrate 10 and are then patterned. After encapsulation for each pixel or over the entire TFT substrate 10, the organic EL display device 19 is completed, which has a plurality of organic EL elements on the TFT substrate 10.

As described above, in this embodiment, the case where the electron transport film (ETL) 14c in the G pixels is formed of the same material as the electron transport film (ETL) 16d in the R and B pixels and is thicker than the electron transport film (ETL) 16d in the R and B pixels is shown as an example where the remaining film percentage of the electron transport film (ETL) 14c in the G pixels after exposure to heat generated by irradiation with laser light is higher than the remaining film percentage of the electron transport film (ETL) 16d in the R and B pixels after exposure to heat generated by irradiation with the laser light. However, this method need not be used. Alternatively, the following method may be used so that the remaining film percentage of the electron transport film (ETL) in the G pixels after exposure to heat generated by irradiation with laser light is higher than the remaining film percentage of the electron transport film (ETL) in the R and B pixels after exposure to heat generated by irradiation with the laser light.

For example, at least a portion of the electron transport film (ETL) 14c in the G pixels shown in FIG. 5 may contain at least one of an inorganic material, an inorganic metal oxide, and a crystalline organic material in a larger amount than the electron transport film (ETL) 16d in the R and B pixels.

If the laser light used in the step of removing the vapor-deposited film including the blue light-emitting film and the red light-emitting film is pulsed laser light with an extremely short duration (e.g., an extremely short duration of the order of femtoseconds (10⁻¹⁵) to picoseconds (10⁻¹²)), the conduction of heat generated by the laser light to other films can be reduced. This allows the amount of at least one of an inorganic material, an inorganic metal oxide, and a crystalline organic material present in the electron transport film (ETL) 14c in the G pixels to be reduced as compared to the use of pulsed laser light with a relatively long duration as described above.

If the electron transport film (ETL) 14c in the G pixels contains a large amount of an inorganic material, an inorganic metal oxide (e.g., an inorganic metal oxide with a low work function (an alkali metal oxide, an alkaline earth metal oxide, or a composite oxide containing such an oxide with a work function of about −3 eV), or a crystalline organic material (e.g., an organic material, such as a phenanthroline-based material, that recrystallizes readily due to its low glass transition), the remaining film percentage of the electron transport film (ETL) 14c after exposure to heat generated by irradiation with laser light and the heat resistance thereof can be improved. This reduces the effect of heat generated by irradiation with laser light on the lower layers. The crystalline organic material is an organic material that has high film density due to crystallization. For example, if an organic material with a low glass transition point (e.g., a glass transition point of lower than 120° C.) is used, the organic material with a low glass transition point crystallizes with heat generated by irradiation with laser light during the step of removing the vapor-deposited film including the blue light-emitting film and the red light-emitting film shown in FIG. 8(b). During this process, heat absorption occurs, thus reducing the effect of heat generated by irradiation with laser light on the lower layers.

Although not shown, the thickness of the electron transport film (ETL) 14c formed in the G pixels may be smaller than or equal to the thickness of the electron transport film (ETL) 16d formed in the R and B pixels, and the electron transport film (ETL) 14c in the G pixels may contain at least one of an inorganic material, an inorganic metal oxide, and a crystalline organic material in a larger amount than the electron transport film (ETL) 16d in the R and B pixels.

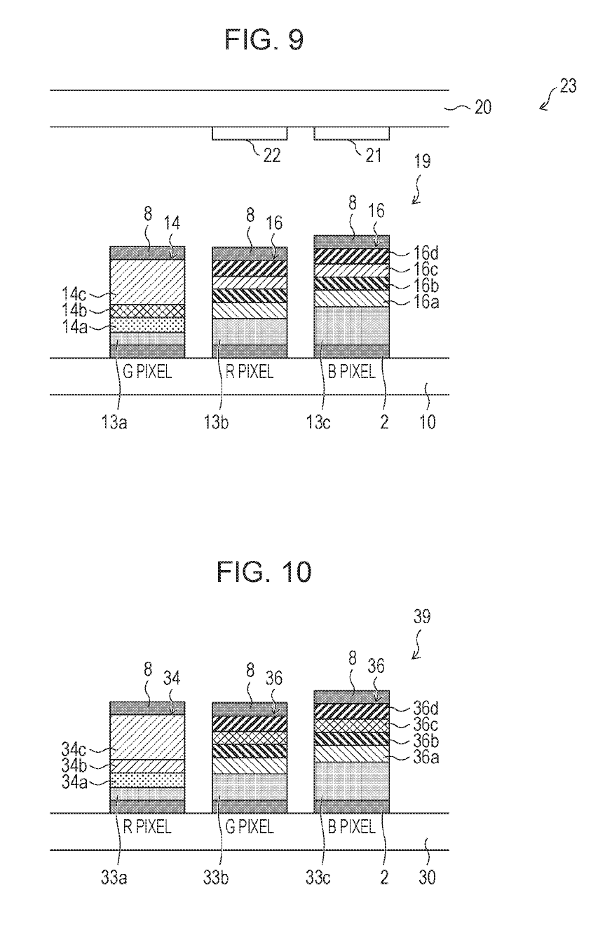

FIG. 9 schematically shows the configuration of an organic EL display device 23 including color filters.

As described above, if the blue light-emitting film (EML(B)) 16b and the red light-emitting film (EML(R)) 16c are formed as common layers in the R and B pixels, color mixing tends to occur in the optical interference design for the blue light-emitting film (EML(B)) 16b and the red light-emitting film (EML(R)) 16c since the peak wavelength of red (600 nm) is about 1.5 times the peak wavelength of blue (450 nm).

Thus, as shown in FIG. 9, it is preferred to provide, for example, blue color filters 21 and red color filters 22 on a glass 20 used in the encapsulation step at the positions opposite the B and R pixels, respectively, to improve the color purity. Although the case where the blue color filters 21 and the red color filters 22 are provided on the glass 20 is shown as an example in this embodiment, this configuration need not be used. Red color filters 22 having a higher transmittance in the wavelength range of red light than in other wavelength ranges may be provided in the paths through which red light is emitted from the R pixels, whereas blue color filters 21 having a higher transmittance in the wavelength range of blue light than in other wavelength ranges may be provided in the paths through which blue light is emitted from the B pixels.

### Third Embodiment

A third embodiment of the present invention will now be described with reference to FIGS. 10 to 13. This embodiment differs from the first and second embodiments in that a vapor-deposited film 34 including a red light-emitting film (EML(R)) 34b is formed in the R pixels before a vapor-deposited film 36 including a blue light-emitting film (EML(B)) 36b and a green light-emitting film (EML(G)) 36c is formed in the G and B pixels. Other details are as described in the first and second embodiments. For illustration purposes, the members having the same functions as those shown in the figures for the first embodiment are denoted by the same reference signs, and a description thereof is omitted.

FIG. 10 schematically shows the configuration of an organic EL display device 39.

As shown, in each R pixel, an anode 2 (reflective electrode), an IZO film 33a, a hole injection film/hole transport film (HIL/HTL) 34a, a red light-emitting film (EML(R)) 34b, an electron transport film (ETL) 34c, an electron injection film (not shown), and a cathode 8 (semitransparent reflective electrode) are stacked in sequence. The electron transport film (ETL) 34c is formed of the same material as an electron transport film (ETL) 36d in the G and B pixels and is thicker than the electron transport film (ETL) 36d.

In each G pixel, an anode 2 (reflective electrode), an IZO film 33b, a hole injection film/hole transport film (HIL/HTL) 36a, a blue light-emitting film (EML(B)) 36b, a green light-emitting film (EML(G)) 36c, an electron transport film (ETL) 36d, an electron injection film (not shown), and a cathode 8 (semitransparent reflective electrode) are stacked in sequence.

In each B pixel, an anode 2 (reflective electrode), an IZO film 33c, a hole injection film/hole transport film (HIL/HTL) 36a, a blue light-emitting film (EML(B)) 36b, a green light-emitting film (EML(G)) 36c, an electron transport film (ETL) 36d, an electron injection film (not shown), and a cathode 8 (semitransparent reflective electrode) are stacked in sequence.

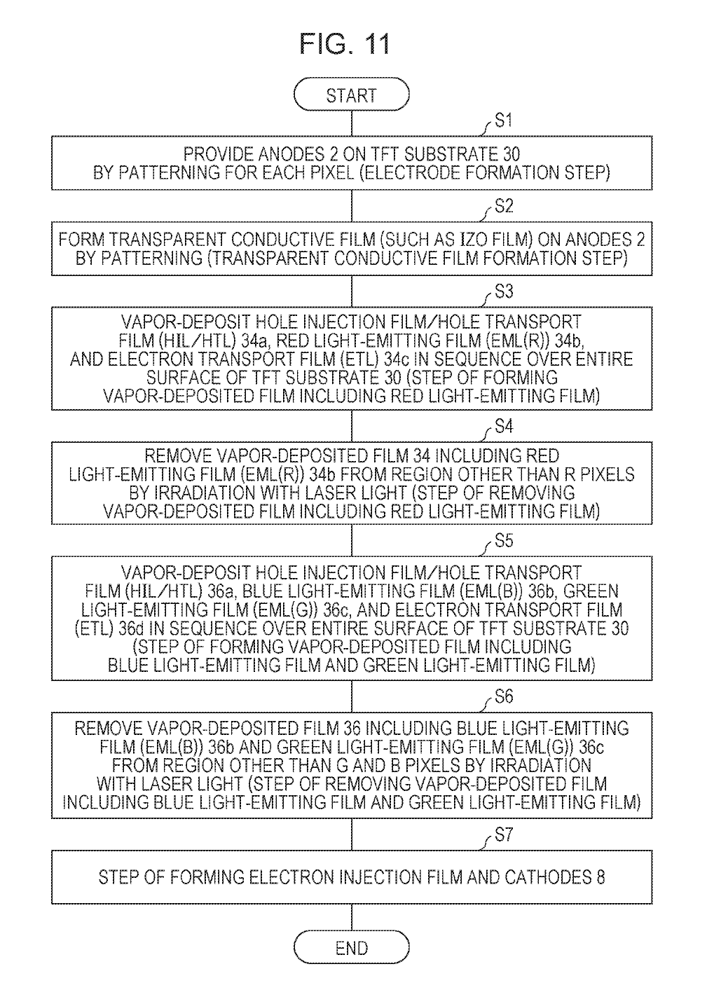

FIG. 11 illustrates a process of manufacturing the organic EL display device 39 shown in FIG. 10.

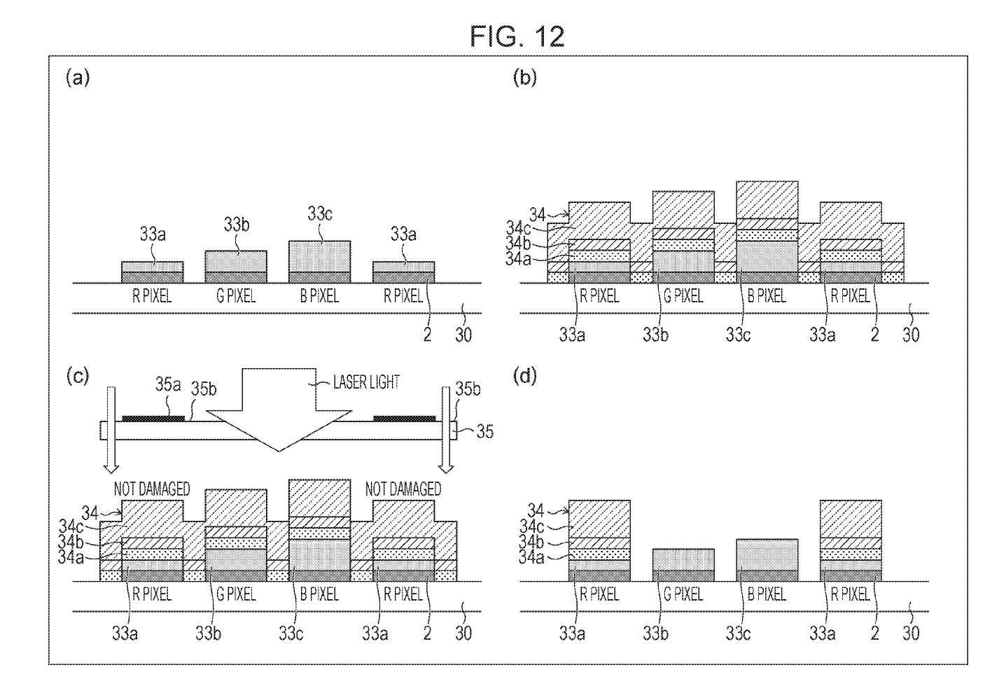

FIGS. 12(a) to 12(d) illustrate a step of forming a vapor-deposited film in the R pixels of the organic EL display device 39.

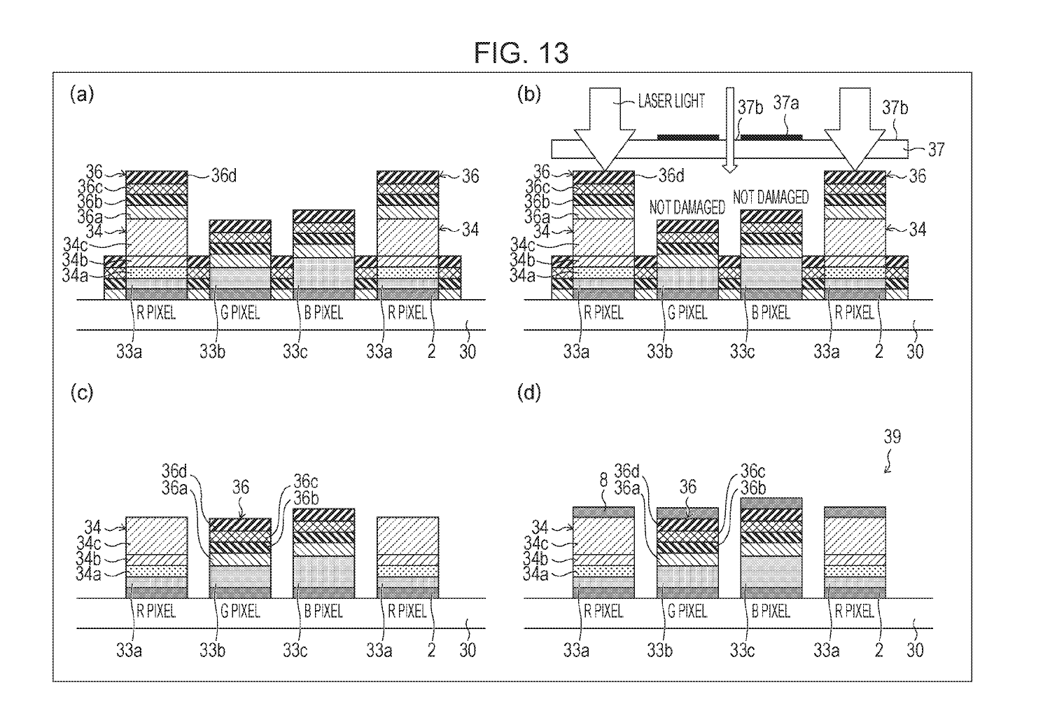

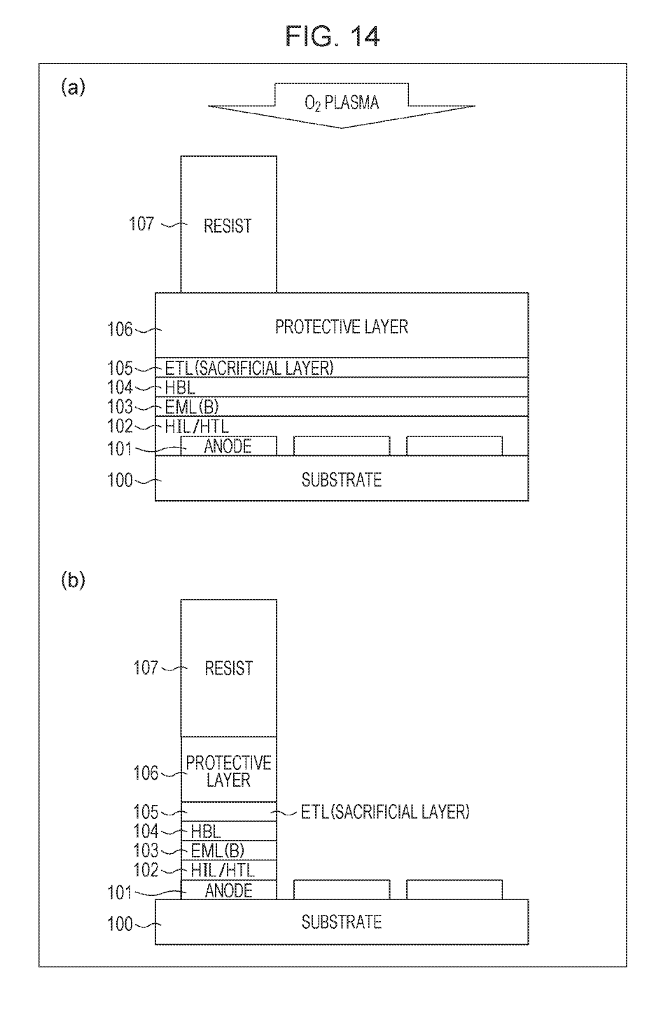

FIGS. 13(a) to 13(d) show an example of a step of forming a vapor-deposited film in the G and B pixels of the organic EL display device 39 after the step shown in FIG. 12(d).

An electrode formation step of providing the anodes 2 on a TFT substrate 30 by patterning for each pixel (S1 in FIG. 11) will be described first. As shown in FIG. 12(a), the anodes 2 are provided on the TFT substrate 30 by patterning for each pixel (R, G, and B pixels) such that the anode 2 in each pixel is electrically connected to the drain electrode (or source electrode) of the TFT provided for that pixel.

A transparent conductive film formation step of forming a transparent conductive film (also referred to as “conductive light-transmissive film”) on the anodes 2 by patterning for each pixel (S2 in FIG. 11) will then be described. The electrode formation step (S1 in FIG. 11) described above and the transparent conductive film formation step (S2 in FIG. 11) are collectively referred to as “anode formation step”.

As shown in FIG. 12(a), the indium zinc oxide (IZO) films 33a, 33b, and 33c, serving as transparent conductive films, are formed on the anodes 2 by patterning. The IZO films 33a, 33b, and 33c are formed so as to have a predetermined thickness for each pixel (R, G, and B pixels) by taking into account the effect of optical interference in each pixel (R, G, and B pixels).

A step of forming a vapor-deposited film including a red light-emitting film (S3 in FIG. 11) will then be described. In this step, the hole injection film/hole transport film (HIL/HTL) 34a, the red light-emitting film (EML(R)) 34b, and the electron transport film (ETL) 34c are vapor-deposited in sequence over the entire surface of the TFT substrate 30.

As shown in FIG. 12(b), the vapor-deposited film 34 including the red light-emitting film (EML(R)) 34b is formed over the entire surface of the TFT substrate 30. As described in detail later, a thick electron transport film (ETL) 34c is formed by taking into account the subsequent steps.

A step of removing the vapor-deposited film including the red light-emitting film (S4 in FIG. 11) will then be described. In this step, the vapor-deposited film 34 including the red light-emitting film (EML(R)) 34b is removed from the region other than the R pixels by irradiation with laser light.

As shown in FIG. 12(c), the vapor-deposited film 34 including the red light-emitting film (EML(R)) 34b is irradiated with laser light through a mask 35 including masking portions 35a and an opening 35b. The masking portions 35a of the mask 35 are located above the R pixel portions of the TFT substrate 30, i.e., above the regions where the IZO film 33a is stacked on the anodes 2, whereas the opening 35b of the mask 35 is located above the region other than the R pixel portions of the TFT substrate 30. Thus, the vapor-deposited film 34 including the red light-emitting film (EML(R)) 34b is irradiated with laser light over the entire region other than the R pixel portions of the TFT substrate 30. Since the vapor-deposited film 34 including the red light-emitting film (EML(R)) 34b is formed of an organic material and the IZO films 33b and 33c are formed of an inorganic material, the vapor-deposited film 34 including the red light-emitting film (EML(R)) 34b is selectively removed from the IZO films 33b and 33c and from the region between the individual pixels by heating with laser light. Thus, as shown in FIG. 12(d), the vapor-deposited film 34 including the red light-emitting film (EML(R)) 34b can be patterned so as to remain only in the R pixels.

As shown in FIG. 12(c), since the masking portions 35a of the mask 35 are located above the R pixels of the TFT substrate 30, the vapor-deposited film 34 including the red light-emitting film (EML(R)) 34b in the R pixels is not irradiated with laser light and is thus not damaged by laser light.

The step of removing the vapor-deposited film including the red light-emitting film is preferably performed in a vacuum atmosphere or an atmosphere having low water and oxygen contents, for example, less than 10 ppm.

As described above, this embodiment uses heating with laser light for patterning. This eliminates the need to form and strip resist films as in conventional methods.

The laser light used in the step of removing the vapor-deposited film including the red light-emitting film is intended to remove, by heating with the laser light, a vapor-deposited film, including a light-emitting film, below which there is no vapor-deposited film, including a light-emitting film, that needs to be protected. It is therefore not necessary to give much consideration to reduce the conduction of heat generated by the laser light to other films. Thus, it is not necessary to use pulsed laser light with an extremely short duration (e.g., an extremely short duration of the order of femtoseconds (10⁻¹⁵) to picoseconds (10⁻¹²)). For example, pulsed laser light with a relatively long duration can be used instead. Although this embodiment uses pulsed laser light with a relatively long duration in the step of removing the vapor-deposited film including the red light-emitting film in order to shorten the process time, this laser light need not be used.

A step of forming a vapor-deposited film including a blue light-emitting film and a green light-emitting film (S5 in FIG. 11) will then be described. In this step, the hole injection film/hole transport film (HIL/HTL) 36a, the blue light-emitting film (EML(B)) 36b, the green light-emitting film (EML(G)) 36c, and the electron transport film (ETL) 36d are vapor-deposited in sequence over the entire surface of the TFT substrate 30.

As shown in FIG. 13(a), the vapor-deposited film 36 including the blue light-emitting film (EML(B)) 36b and the green light-emitting film (EML(G)) 36c is formed over the entire surface of the TFT substrate 30.

As described above, the blue light-emitting film (EML(B)) 36b and the green light-emitting film (EML(G)) 36c are formed as common layers in the G and B pixels.

In this embodiment, the vapor-deposited film 36 including the blue light-emitting film (EML(B)) 36b and the green light-emitting film 36c is vapor-deposited such that the lower layer is the blue light-emitting film (EML(B)) 36b and the upper layer is the green light-emitting film (EML(G)) 36c from the standpoint of carrier characteristics, that is, electron-hole recombination balance. Alternatively, the vapor-deposited film 36 including the blue light-emitting film (EML(B)) 36b and the green light-emitting film (EML(G)) 36c may be vapor-deposited such that the lower layer is the green light-emitting film (EML(G)) 36c and the upper layer is the blue light-emitting film (EML(B)) 36b. In this case, it should only be noted that the thicknesses of the IZO films 33b and 33c are changed.

A step of removing the vapor-deposited film including the blue light-emitting film and the green light-emitting film (S6 in FIG. 11) will then be described. In this step, the vapor-deposited film 36 including the blue light-emitting film (EML(B)) 36b and the green light-emitting film (EML(G)) 36c is removed from the region other than the G and B pixels by irradiation with laser light.

As shown in FIG. 13(b), the vapor-deposited film 36 including the blue light-emitting film (EML(B)) 36b and the green light-emitting film (EML(G)) 36c is irradiated with laser light through a mask 37 including masking portions 37a and an opening 37b. The masking portions 37a of the mask 37 are located above the G and B pixel portions of the TFT substrate 30, i.e., above the regions where the IZO film 33b is stacked on the anodes 2 and the regions where the IZO film 33c is stacked on the anodes 2, whereas the opening 37b of the mask 37 is located above the region other than the G and B pixel portions of the TFT substrate 30. Thus, the vapor-deposited film 36 including the blue light-emitting film (EML(B)) 36b and the green light-emitting film (EML(G)) 36c is irradiated with laser light over the entire region other than the G and B pixel portions of the TFT substrate 30. Since the vapor-deposited film 36 including the blue light-emitting film (EML(B)) 36b and the green light-emitting film (EML(G)) 36c is formed of an organic material, the vapor-deposited film 36 including the blue light-emitting film (EML(B)) 36b and the green light-emitting film (EML(G)) 36c is selectively removed from the R pixel portions of the TFT substrate 30 and from the region between the individual pixels by heating with laser light. Thus, as shown in FIG. 13(c), the vapor-deposited film 34 including the red light-emitting film (EML(R)) 34b can be patterned so as to remain on the R pixel portions of the TFT substrate 30, whereas the vapor-deposited film 36 including the blue light-emitting film (EML(B)) 36b and the green light-emitting film (EML(G)) 36c can be patterned so as to remain on the G and B pixel portions of the TFT substrate 30.

As shown in FIG. 13(b), since the masking portions 37a of the mask 37 are located above the G and B pixels of the TFT substrate 30, the vapor-deposited film 36 including the blue light-emitting film (EML(B)) 36b and the green light-emitting film (EML(G)) 36c in the G and B pixels is not irradiated with laser light and is thus not damaged by laser light.

The vapor-deposited film 34, including the red light-emitting film (EML(R)) 34b, formed on the R pixel portions of the TFT substrate 30 includes a thick electron transport film (ETL) 34c formed on the assumption that the laser light used in the step of removing the vapor-deposited film including the blue light-emitting film and the green light-emitting film is the pulsed laser light with a relatively long duration used in the step of removing the vapor-deposited film including the red light-emitting film. This is intended to minimize the effect of heat generated by irradiation with laser light on the red light-emitting film (EML(R)) 34b and the hole injection film/hole transport film (HIL/HTL) 34a during the step of removing the vapor-deposited film 36, including the blue light-emitting film (EML(B)) 36b and the green light-emitting film (EML(G)) 36c, formed on the vapor-deposited film 34 including the red light-emitting film (EML(R)) 34b in the R pixels. The electron transport film (ETL) 34c in the R pixels also tends to have variations in thickness (e.g., damage during pattering) because of the process characteristics, i.e., the use of heat generated by irradiation with laser light for patterning. Thus, it is preferred to form a thick electron transport film (ETL) 34c in the R pixels so that less color change occurs. As the electron transport film (ETL) 34c becomes thicker, the entire vapor-deposited film 34 including the red light-emitting film (EML(R)) 34b becomes thicker.

In this embodiment, the electron transport film (ETL) 34c in the R pixels is formed of the same material as the electron transport film (ETL) 36d in the G and B pixels and is thicker than the electron transport film (ETL) 36d in the G and B pixels so that the remaining film percentage of the electron transport film (ETL) 34c in the R pixels after exposure to heat generated by irradiation with laser light is higher than the remaining film percentage of the electron transport film (ETL) 36d in the G and B pixels after exposure to heat generated by irradiation with the laser light.

If the laser light used in the step of removing the vapor-deposited film including the blue light-emitting film and the green light-emitting film is pulsed laser light with an extremely short duration (e.g., an extremely short duration of the order of femtoseconds (10⁻¹⁵) to picoseconds (10⁻¹²)), the conduction of heat generated by the laser light to other films can be reduced. This allows a thin electron transport film (ETL) 34c to be formed as compared to the use of pulsed laser light with a relatively long duration as described above. The step of removing the vapor-deposited film including the blue light-emitting film and the green light-emitting film is preferably performed in a vacuum atmosphere or an atmosphere containing less than 10 ppm water and oxygen.

Finally, a step of forming the electron injection film and the cathodes 8 (S7 in FIG. 11) will be described.

As shown in FIG. 13(d), the electron injection film (not shown) and the cathodes 8 are formed in sequence over the entire surface of the TFT substrate 30 and are then patterned. After encapsulation for each pixel or over the entire TFT substrate 30, the organic EL display device 39 is completed, which has a plurality of organic EL elements on the TFT substrate 30.

As described above, in this embodiment, the case where the electron transport film (ETL) 34c in the R pixels is formed of the same material as the electron transport film (ETL) 36d in the G and B pixels and is thicker than the electron transport film (ETL) 36d in the G and B pixels is shown as an example where the remaining film percentage of the electron transport film (ETL) 34c in the R pixels after exposure to heat generated by irradiation with laser light is higher than the remaining film percentage of the electron transport film (ETL) 36d in the G and B pixels after exposure to heat generated by irradiation with the laser light. However, this method need not be used. Alternatively, the following method may be used so that the remaining film percentage of the electron transport film (ETL) in the R pixels after exposure to heat generated by irradiation with laser light is higher than the remaining film percentage of the electron transport film (ETL) in the G and B pixels after exposure to heat generated by irradiation with the laser light.

For example, at least a portion of the electron transport film (ETL) 34c in the R pixels shown in FIG. 10 may contain at least one of an inorganic material, an inorganic metal oxide, and a crystalline organic material in a larger amount than the electron transport film (ETL) 36d in the G and B pixels.

If the laser light used in the step of removing the vapor-deposited film including the blue light-emitting film and the green light-emitting film is pulsed laser light with an extremely short duration (e.g., an extremely short duration of the order of femtoseconds (10⁻¹⁵) to picoseconds (10⁻¹²)), the conduction of heat generated by the laser light to other films can be reduced. This allows the amount of at least one of an inorganic material, an inorganic metal oxide, and a crystalline organic material present in the electron transport film (ETL) 34c in the R pixels to be reduced as compared to the use of pulsed laser light with a relatively long duration as described above.

If the electron transport film (ETL) 34c in the R pixels contains a large amount of an inorganic material, an inorganic metal oxide (e.g., an inorganic metal oxide with a low work function (an alkali metal oxide, an alkaline earth metal oxide, or a composite oxide containing such an oxide with a work function of about −3 eV), or a crystalline organic material (e.g., an organic material, such as a phenanthroline-based material, that recrystallizes readily due to its low glass transition), the remaining film percentage of the electron transport film (ETL) 34c after exposure to heat generated by irradiation with laser light and the heat resistance thereof can be improved. This reduces the effect of heat generated by irradiation with laser light on the lower layers. The crystalline organic material is an organic material that has high film density due to crystallization. For example, if an organic material with a low glass transition point (e.g., a glass transition point of lower than 120° C.) is used, the organic material with a low glass transition point crystallizes with heat generated by irradiation with laser light during the step of removing the vapor-deposited film including the blue light-emitting film and the green light-emitting film shown in FIG. 13(b). During this process, heat absorption occurs, thus reducing the effect of heat generated by irradiation with laser light on the lower layers.

Although not shown, the thickness of the electron transport film (ETL) 34c formed in the R pixels may be smaller than or equal to the thickness of the electron transport film (ETL) 36d formed in the G and B pixels, and the electron transport film (ETL) 34e in the R pixels may contain at least one of an inorganic material, an inorganic metal oxide, and a crystalline organic material in a larger amount than the electron transport film (ETL) 36d in the G and B pixels.

### Summary

A display device according to a first aspect of the present invention includes first and second pixels configured to emit light with different peak wavelengths and a reflective electrode and a semitransparent reflective electrode provided in each pixel. A first light-emitting film is formed in the first pixel, and a second light-emitting film is formed in the second pixel. The remaining film percentage of a vapor-deposited film formed on the first light-emitting film after exposure to heat generated by irradiation with laser light is higher than the remaining film percentage of a vapor-deposited film formed on the second light-emitting film after exposure to heat generated by irradiation with laser light.

In this configuration, the remaining film percentage of the vapor-deposited film formed on the first light-emitting film after exposure to heat generated by irradiation with laser light is higher than the remaining film percentage of the vapor-deposited film formed on the second light-emitting film after exposure to heat generated by irradiation with laser light. Therefore, for example, if the second light-emitting film and the vapor-deposited film formed on the second light-emitting film are formed on the vapor-deposited film formed on the first light-emitting film and are removed by heating with laser light during the process of manufacturing the display device in order to achieve improved productivity, the effect of the heat on the first light-emitting film and the vapor-deposited film formed below the first light-emitting film can be reduced. Thus, a display device with high productivity and with reduced color shift in light-emitting elements and reduced degradation in light-emitting element characteristics can be achieved.

According to a second aspect of the present invention, the display device according to the first aspect preferably further includes a third pixel configured to emit light with a peak wavelength different from the peak wavelengths of the first and second pixels and a reflective electrode and a semitransparent reflective electrode provided in the third pixel. A stack of the second light-emitting film and a third light-emitting film is preferably formed in each of the second and third pixels. The distance between the reflective electrode and the second light-emitting film in the second pixel is preferably set such that light with the peak wavelength of the second pixel is output from the semitransparent reflective electrode. The distance between the reflective electrode and the third light-emitting film in the third pixel is preferably set such that light with the peak wavelength of the third pixel is output from the semitransparent reflective electrode. The remaining film percentage of the vapor-deposited film formed on the first light-emitting film after exposure to heat generated by irradiation with laser light is preferably higher than the remaining film percentage of the vapor-deposited film formed on the second light-emitting film after exposure to heat generated by irradiation with laser light, the second light-emitting film being the upper layer of the stack of the second light-emitting film and the third light-emitting film.

In this configuration, the second light-emitting film and the third light-emitting film are both formed in each of the second and third pixels. Therefore, the second light-emitting film and the third light-emitting film in each of the second and third pixels can be formed by patterning in a single step. This results in high productivity and reduced adverse effect on other films during patterning.

In addition, in this configuration, in which the second light-emitting film and the third light-emitting film are both formed in each of the second and third pixels, the distance between the reflective electrode and the second light-emitting film in the second pixel is set such that light with the peak wavelength of the second pixel is output from the semitransparent reflective electrode, and the distance between the reflective electrode and the third light-emitting film in the third pixel is set such that light with the peak wavelength of the third pixel is output from the semitransparent reflective electrode. Thus, light with a predetermined peak wavelength can be output from each pixel.

In addition, the remaining film percentage of the vapor-deposited film formed on the first light-emitting film after exposure to heat generated by irradiation with laser light is higher than the remaining film percentage of the vapor-deposited film formed on the second light-emitting film after exposure to heat generated by irradiation with laser light, the second light-emitting film being the upper layer of the stack of the second light-emitting film and the third light-emitting film. Therefore, for example, when any film on the vapor-deposited film formed on the first light-emitting film is removed by heating with laser light, the effect of the heat on the first light-emitting film and the vapor-deposited film formed below the first light-emitting film can be reduced. Thus, a display device with reduced color shift in light-emitting elements and reduced degradation in light-emitting element characteristics can be achieved.

According to a third aspect of the present invention, in the display device according to the first or second aspect, the vapor-deposited film formed on the first light-emitting film may be thicker than the vapor-deposited film formed on the second light-emitting film.

In this configuration, the vapor-deposited film formed on the first light-emitting film is thicker than the vapor-deposited film formed on the second light-emitting film. Therefore, for example, when any film on the vapor-deposited film formed on the first light-emitting film is removed by heating with laser light, the effect of the heat on the first light-emitting film and the vapor-deposited film formed on the first light-emitting film can be reduced. Thus, a display device with reduced color shift in light-emitting elements and reduced degradation in light-emitting element characteristics can be achieved.

According to a fourth aspect of the present invention, in the display device according to any one of the first to third aspects, the vapor-deposited film formed on the first light-emitting film may contain at least one of an inorganic material, an inorganic metal oxide, and a crystalline organic material in a larger amount than the vapor-deposited film formed on the second light-emitting film.

In this configuration, the vapor-deposited film formed on the first light-emitting film contains at least one of an inorganic material, an inorganic metal oxide, and a crystalline organic material in a larger amount than the vapor-deposited film formed on the second light-emitting film. Therefore, for example, when any film on the vapor-deposited film formed on the first light-emitting film is removed by heating with laser light, the effect of the heat on the first light-emitting film and the vapor-deposited film formed on the first light-emitting film can be reduced. Thus, a display device with reduced color shift in light-emitting elements and reduced degradation in light-emitting element characteristics can be achieved.

According to a fifth aspect of the present invention, in the display device according to the second aspect, the distance between the reflective electrode and the second light-emitting film in the second pixel is preferably ¼ of the peak wavelength of the second pixel×(2N−1), where N is a natural number. The distance between the reflective electrode and the third light-emitting film in the third pixel is preferably ¼ of the peak wavelength of the third pixel×(2N−1), where N is a natural number.

With this configuration, light with a predetermined peak wavelength can be efficiently output from each pixel.

According to a sixth aspect of the present invention, in the display device according to the second or fifth aspect, the first light-emitting film may be a blue light-emitting film. The second light-emitting film may be one of a green light-emitting film and a red light-emitting film. The third light-emitting film may be the other of the green light-emitting film and the red light-emitting film.

In this configuration, the green light-emitting film and the red light-emitting film are formed as common layers in the second and third pixels. In this case, phosphorescent materials are used as dopants, and a common host material can be used. Thus, it is only necessary to change the dopant in the vapor deposition step.

According to a seventh aspect of the present invention, in the display device according to the second or fifth aspect, the first light-emitting film may be a green light-emitting film. The second light-emitting film may be one of a red light-emitting film and a blue light-emitting film. The third light-emitting film may be the other of the red light-emitting film and the blue light-emitting film.

With this configuration, a display device in which a red light-emitting film and a blue light-emitting film are formed as common layers in second and third pixels can be achieved.

According to an eighth aspect of the present invention, in the display device according to the second or fifth aspect, the first light-emitting film may be a red light-emitting film. The second light-emitting film may be one of a green light-emitting film and a blue light-emitting film. The third light-emitting film may be the other of the green light-emitting film and the blue light-emitting film.

With this configuration, a display device in which a green light-emitting film and a blue light-emitting film are formed as common layers in second and third pixels can be achieved.

According to a ninth aspect of the present invention, the display device according to any one of the fifth to eighth aspects preferably further includes a color filter provided in a path through which light with the peak wavelength of the second pixel is emitted from the second pixel, the color filter having a higher transmittance in the wavelength range of light with the peak wavelength of the second pixel than in other wavelength ranges, and a color filter provided in a path through which light with the peak wavelength of the third pixel is emitted from the third pixel, the color filter having a higher transmittance in the wavelength range of light with the peak wavelength of the third pixel than in other wavelength ranges.

With this configuration, a display device with high color purity can be achieved.

A method for manufacturing a display device according to a tenth aspect of the present invention is a method for manufacturing a display device including first and second pixels provided on a substrate and configured to emit light with different peak wavelengths and a light-emitting film, a reflective electrode, and a semitransparent reflective electrode provided in each pixel. This method includes a conductive light-transmissive film formation step of forming a conductive light-transmissive film having a predetermined thickness in each pixel to adjust the distance between the light-emitting film and the reflective electrode such that light with the peak wavelength of the pixel is output from the semitransparent reflective electrode; a first vapor-deposited film formation step of forming a first vapor-deposited film including, of the light-emitting films, a first light-emitting film over an entire surface of the substrate including the first and second pixels; a step of removing the first vapor-deposited film including the first light-emitting film from a region other than the first pixel with laser light; a second vapor-deposited film formation step of forming a second vapor-deposited film including, of the light-emitting films, a second light-emitting film over the entire surface of the substrate including the first and second pixels; and a step of removing the second vapor-deposited film including the second light-emitting film from a region other than the second pixel with laser light. The remaining film percentage of a vapor-deposited film formed on the first light-emitting film in the first vapor-deposited film formation step after exposure to heat generated by irradiation with laser light is higher than the remaining film percentage of a vapor-deposited film formed on the second light-emitting film in the second vapor-deposited film formation step after exposure to heat generated by irradiation with laser light.

In this method, the remaining film percentage of the vapor-deposited film formed on the first light-emitting film in the first vapor-deposited film formation step after exposure to heat generated by irradiation with laser light is higher than the remaining film percentage of the vapor-deposited film formed on the second light-emitting film in the second vapor-deposited film formation step after exposure to heat generated by irradiation with laser light. Therefore, when any film on the vapor-deposited film formed on the first light-emitting film is removed by heating with laser light in the step of removing the second vapor-deposited film including the second light-emitting film from the region other than the second pixel with laser light, the effect of the heat on the first light-emitting film and the vapor-deposited film formed below the first light-emitting film can be reduced. Thus, a method for manufacturing a display device with reduced color shift in light-emitting elements and reduced degradation in light-emitting element characteristics can be achieved.

According to an eleventh aspect of the present invention, in the method for manufacturing the display device according to the tenth aspect, the display device preferably further includes a third pixel provided on the substrate and configured to emit light with a peak wavelength different from the peak wavelengths of the first and second pixels and a reflective electrode and a semitransparent reflective electrode provided in the third pixel. In the second vapor-deposited film formation step, a second vapor-deposited film including a stack of the second light-emitting film and a third light-emitting film is preferably formed over an entire surface of the substrate including the first, second, and third pixels. In the step of removing the second vapor-deposited film including the second light-emitting film, the second vapor-deposited film including the stack of the second light-emitting film and the third light-emitting film is preferably removed from a region other than the second and third pixels with laser light. In the conductive light-transmissive film formation step, a conductive light-transmissive film having a predetermined thickness is preferably formed in the second pixel to adjust the distance between the reflective electrode and the second light-emitting film in the second pixel such that light with the peak wavelength of the second pixel is output from the semitransparent reflective electrode. A conductive light-transmissive film having a predetermined thickness is preferably formed in the third pixel to adjust the distance between the reflective electrode and the third light-emitting film in the third pixel such that light with the peak wavelength of the third pixel is output from the semitransparent reflective electrode. The remaining film percentage of the vapor-deposited film formed on the first light-emitting film in the first vapor-deposited film formation step after exposure to heat generated by irradiation with laser light is preferably higher than the remaining film percentage of the vapor-deposited film formed on the second light-emitting film in the second vapor-deposited film formation step after exposure to heat generated by irradiation with laser light, the second light-emitting film being the upper layer of the stack of the second light-emitting film and the third light-emitting film.

In this method, vapor-deposited films including light-emitting films of individual colors can be patterned by two vapor-deposited film formation steps, i.e., the first vapor-deposited film formation step and the second vapor-deposited film formation step, and two vapor-deposited film removal steps, i.e., the step of removing the first vapor-deposited film and the step of removing the second vapor-deposited film. Thus, this method offers high productivity and reduced adverse effect on other films during patterning as compared to conventional methods in which films including light-emitting films of individual colors need to be vapor-deposited for each color pixel.

In addition, in this method, vapor-deposited films including light-emitting films of individual colors are patterned with laser light. Specifically, vapor-deposited films including light-emitting films of individual colors are patterned by partially removing the vapor-deposited films by heating with laser light. Thus, this method does not require three resist formation steps and three resist stripping steps as in conventional methods, thus offering improved productivity and reduced adverse effect on other films during resist photolithography.

In addition, the remaining film percentage of the vapor-deposited film formed on the first light-emitting film in the first vapor-deposited film formation step after exposure to heat generated by irradiation with laser light is higher than the remaining film percentage of the vapor-deposited film formed on the second light-emitting film, which is the upper layer, in the second vapor-deposited film formation step after exposure to heat generated by irradiation with laser light. Therefore, for example, when any film on the vapor-deposited film formed on the first light-emitting film is removed by heating with laser light, the effect of the heat on the first light-emitting film and the vapor-deposited film formed below the first light-emitting film can be reduced. Thus, a method for manufacturing a display device with reduced color shift in light-emitting elements and reduced degradation in light-emitting element characteristics can be achieved.

Thus, a method for manufacturing a display device with high productivity and with reduced color shift in light-emitting elements and reduced degradation in light-emitting element characteristics can be achieved.

According to a twelfth aspect of the present invention, in the method for manufacturing the display device according to the tenth or eleventh aspect, the vapor-deposited film formed on the first light-emitting film in the first vapor-deposited film formation step may be thicker than the vapor-deposited film formed on the second light-emitting film in the second vapor-deposited film formation step.

In this method, the vapor-deposited film formed on the first light-emitting film is thicker than the vapor-deposited film formed on the second light-emitting film. Therefore, for example, when any film on the vapor-deposited film formed on the first light-emitting film is removed by heating with laser light, the effect of the heat on the first light-emitting film and the vapor-deposited film formed on the first light-emitting film can be reduced. Thus, a method for manufacturing a display device with reduced color shift in light-emitting elements and reduced degradation in light-emitting element characteristics can be achieved.

According to a thirteenth aspect of the present invention, in the method for manufacturing the display device according to any one of the tenth to twelfth aspects, the vapor-deposited film formed on the first light-emitting film in the first vapor-deposited film formation step may contain at least one of an inorganic material, an inorganic metal oxide, and a crystalline organic material in a larger amount than the vapor-deposited film formed on the second light-emitting film in the second vapor-deposited film formation step.

In this method, the vapor-deposited film formed on the first light-emitting film contains at least one of an inorganic material, an inorganic metal oxide, and a crystalline organic material in a larger amount than the vapor-deposited film formed on the second light-emitting film. Therefore, for example, when any film on the vapor-deposited film formed on the first light-emitting film is removed by heating with laser light, the effect of the heat on the first light-emitting film and the vapor-deposited film formed on the first light-emitting film can be reduced. Thus, a method for manufacturing a display device with reduced color shift in light-emitting elements and reduced degradation in light-emitting element characteristics can be achieved.

According to a fourteenth aspect of the present invention, in the method for manufacturing the display device according to any one of the tenth to thirteenth aspects, a mask configured to partially block the laser light is preferably used in the step of removing the first vapor-deposited film or the step of removing the second vapor-deposited film.

Since this method uses a mask, accurate patterning with laser light can be performed while laser light is blocked in the region where no mask is required. This results in reduced adverse effect on other films.

According to a fifteenth aspect of the present invention, in the method for manufacturing the display device according to any one of the tenth to fourteenth aspects, the step of removing the first vapor-deposited film or the step of removing the second vapor-deposited film is preferably performed in a vacuum atmosphere or an atmosphere containing less than 10 ppm water and oxygen.

With this method, patterning with laser light can be more efficiently performed.

According to a sixteenth aspect of the present invention, in the method for manufacturing the display device according to any one of the tenth to fifteenth aspects, pulsed laser light with an extremely short duration of 10⁻¹⁵ to 10⁻¹² seconds is preferably used in the step of removing the second vapor-deposited film.

Since this method uses pulsed laser light with an extremely short duration of 10⁻¹⁵ to 10⁻¹² seconds, the conduction of heat generated by laser light to other films can be reduced.

According to a seventeenth aspect of the present invention, in the method for manufacturing the display device according to the eleventh aspect, the conductive light-transmissive films formed in the conductive light-transmissive film formation step preferably have such thicknesses that the distance between the reflective electrode and the second light-emitting film in the second pixel is ¼ of the peak wavelength of the second pixel×(2N−1) (where N is a natural number) and that the distance between the reflective electrode and the third light-emitting film in the third pixel is ¼ of the peak wavelength of the third pixel×(2N−1) (where N is a natural number).

With this method, light with a predetermined peak wavelength can be efficiently output from each pixel.

According to an eighteenth aspect of the present invention, in the method for manufacturing the display device according to the eleventh or seventeenth aspect, the first light-emitting film may be a blue light-emitting film. The second light-emitting film may be one of a green light-emitting film and a red light-emitting film. The third light-emitting film may be the other of the green light-emitting film and the red light-emitting film.

In this method, the red light-emitting film and the blue light-emitting film are formed as common layers in the second and third pixels. In this case, phosphorescent materials are used as dopants, and a common host material can be used. Thus, it is only necessary to change the dopant in the vapor deposition step.

According to a nineteenth aspect of the present invention, in the method for manufacturing the display device according to the eleventh or seventeenth aspect, the first light-emitting film may be a green light-emitting film. The second light-emitting film may be one of a red light-emitting film and a blue light-emitting film. The third light-emitting film may be the other of the red light-emitting film and the blue light-emitting film.

With this method, a display device in which a red light-emitting film and a blue light-emitting film are formed as common layers in second and third pixels can be manufactured.

According to a twentieth aspect of the present invention, in the method for manufacturing the display device according to the eleventh or seventeenth aspect, the first light-emitting film may be a red light-emitting film. The second light-emitting film may be one of a green light-emitting film and a blue light-emitting film. The third light-emitting film may be the other of the green light-emitting film and the blue light-emitting film.

With this method, a display device in which a green light-emitting film and a blue light-emitting film are formed as common layers in second and third pixels can be manufactured.

According to a twenty-first aspect of the present invention, the method for manufacturing the display device according to any one of the seventeenth to twentieth aspects preferably further includes a step of providing a color filter in a path through which light with the peak wavelength of the second pixel is emitted from the second pixel, the color filter having a higher transmittance in the wavelength range of light with the peak wavelength of the second pixel than in other wavelength ranges, and providing a color filter in a path through which light with the peak wavelength of the third pixel is emitted from the third pixel, the color filter having a higher transmittance in the wavelength range of light with the peak wavelength of the third pixel than in other wavelength ranges.

With this method, a method for manufacturing a display device with high color purity can be achieved.

Supplementary Note

The present invention is not limited to the foregoing embodiments. Various modifications can be made within the scope indicated by the claims, and embodiments including suitable combinations of technical means disclosed in different embodiments are also included in the technical scope of the invention. The technical means disclosed in the embodiments can also be combined together to form new technical features.

### INDUSTRIAL APPLICABILITY

The present invention is applicable to display devices, particularly organic EL display devices and methods for manufacturing such display devices.

### REFERENCE SIGNS LIST

1 TFT substrate
2 anode (reflective electrode)
3a IZO film (conductive light-transmissive film)
3b IZO film (conductive light-transmissive film)
3c IZO film (conductive light-transmissive film)
4 vapor-deposited film including blue light-emitting film
4a hole injection film/hole transport film in B pixel
4b blue light-emitting film
4c electron transport film in B pixel
5 mask
5a masking portion
5b opening
6 vapor-deposited film including green light-emitting film and red light-emitting film
6a hole injection film/hole transport film in G and R pixels
6b green light-emitting film
6c red light-emitting film
6d electron transport film in G and R pixels
7 mask
7a masking portion
7b opening
8 cathode (semitransparent reflective electrode)
9 organic EL display device (display device)
10 TFT substrate
13a IZO film (conductive light-transmissive film)
13b IZO film (conductive light-transmissive film)
13c IZO film (conductive light-transmissive film)
14 vapor-deposited film including green light-emitting film
14a hole injection film/hole transport film in G pixel
14b green light-emitting film
14c electron transport film in G pixel
15 mask
15a masking portion
15b opening
16 vapor-deposited film including blue light-emitting film and red light-emitting film
16a hole injection film/hole transport film in R and B pixels
16b blue light-emitting film
16c red light-emitting film
16d electron transport film in R and B pixels
17 mask
17a masking portion
17b opening
19 organic EL display device (display device)
20 glass
21 blue color filter (color filter with high transmittance in wavelength range of blue light)
22 red color filter (color filter with high transmittance in wavelength range of red light)
23 organic EL display device (display device)
30 TFT substrate
33a IZO film (conductive light-transmissive film)
33b IZO film (conductive light-transmissive film)
33c IZO film (conductive light-transmissive film)
34 vapor-deposited film including red light-emitting film
34a hole injection film/hole transport film in R pixel
34b red light-emitting film
34c electron transport film in R pixel
35 mask
35a masking portion
35b opening
36 vapor-deposited film including blue light-emitting film and green light-emitting film
36a hole injection film/hole transport film in G and B pixels
36b blue light-emitting film
36c green light-emitting film
36d electron transport film in G and B pixels
37 mask
37a masking portion
37b opening
39 organic EL display device (display device)

1-21. (canceled)

22: A display device comprising first and second pixels configured to emit light with different peak wavelengths and a reflective electrode and a semitransparent reflective electrode provided in each pixel,
wherein a first light-emitting film is formed in the first pixel, and a second light-emitting film is formed in the second pixel, and
wherein a remaining film percentage of a vapor-deposited film formed on the first light-emitting film after exposure to heat generated by irradiation with laser light is higher than a remaining film percentage of a vapor-deposited film formed on the second light-emitting film after exposure to heat generated by irradiation with laser light,
further comprising a third pixel configured to emit light with a peak wavelength different from the peak wavelengths of the first and second pixels and a reflective electrode and a semitransparent reflective electrode provided in the third pixel,
wherein a stack of the second light-emitting film and a third light-emitting film is formed in each of the second and third pixels,
wherein a distance between the reflective electrode and the second light-emitting film in the second pixel is set such that light with the peak wavelength of the second pixel is output from the semitransparent reflective electrode, and a distance between the reflective electrode and the third light-emitting film in the third pixel is set such that light with the peak wavelength of the third pixel is output from the semitransparent reflective electrode, and
wherein the remaining film percentage of the vapor-deposited film formed on the first light-emitting film after exposure to heat generated by irradiation with laser light is higher than the remaining film percentage of the vapor-deposited film formed on the second light-emitting film after exposure to heat generated by irradiation with laser light, the second light-emitting film being an upper layer of the stack of the second light-emitting film and the third light-emitting film.

23: The display device according to claim 22, wherein the vapor-deposited film formed on the first light-emitting film is thicker than the vapor-deposited film formed on the second light-emitting film.

24: The display device according to claim 22, wherein the vapor-deposited film formed on the first light-emitting film contains at least one of an inorganic material, an inorganic metal oxide, and a crystalline organic material in a larger amount than the vapor-deposited film formed on the second light-emitting film.

25: The display device according to claim 22, wherein the distance between the reflective electrode and the second light-emitting film in the second pixel is ¼ of the peak wavelength of the second pixel×(2N−1), wherein N is a natural number, and the distance between the reflective electrode and the third light-emitting film in the third pixel is ¼ of the peak wavelength of the third pixel×(2N−1), wherein N is a natural number.

26: The display device according to claim 22, wherein
the first light-emitting film is a blue light-emitting film,
the second light-emitting film is one of a green light-emitting film and a red light-emitting film, and
the third light-emitting film is the other of the green light-emitting film and the red light-emitting film.

27: The display device according to claim 22, wherein
the first light-emitting film is a green light-emitting film,
the second light-emitting film is one of a red light-emitting film and a blue light-emitting film, and
the third light-emitting film is the other of the red light-emitting film and the blue light-emitting film.

28: The display device according to claim 22, wherein
the first light-emitting film is a red light-emitting film,
the second light-emitting film is one of a green light-emitting film and a blue light-emitting film, and
the third light-emitting film is the other of the green light-emitting film and the blue light-emitting film.

29: The display device according to claim 25, further comprising a color filter provided in a path through which light with the peak wavelength of the second pixel is emitted from the second pixel, the color filter having a higher transmittance in a wavelength range of light with the peak wavelength of the second pixel than in other wavelength ranges, and a color filter provided in a path through which light with the peak wavelength of the third pixel is emitted from the third pixel, the color filter having a higher transmittance in a wavelength range of light with the peak wavelength of the third pixel than in other wavelength ranges.

30: A method for manufacturing a display device comprising first and second pixels provided on a substrate and configured to emit light with different peak wavelengths and a light-emitting film, a reflective electrode, and a semitransparent reflective electrode provided in each pixel, the method comprising:
a conductive light-transmissive film formation step of forming a conductive light-transmissive film having a predetermined thickness in each pixel to adjust a distance between the light-emitting film and the reflective electrode such that light with the peak wavelength of the pixel is output from the semitransparent reflective electrode;
a first vapor-deposited film formation step of forming a first vapor-deposited film including, of the light-emitting films, a first light-emitting film over an entire surface of the substrate including the first and second pixels;
a step of removing the first vapor-deposited film including the first light-emitting film from a region other than the first pixel with laser light;
a second vapor-deposited film formation step of forming a second vapor-deposited film including, of the light-emitting films, a second light-emitting film over the entire surface of the substrate including the first and second pixels; and
a step of removing the second vapor-deposited film including the second light-emitting film from a region other than the second pixel with laser light,
wherein a remaining film percentage of a vapor-deposited film formed on the first light-emitting film in the first vapor-deposited film formation step after exposure to heat generated by irradiation with laser light is higher than a remaining film percentage of a vapor-deposited film formed on the second light-emitting film in the second vapor-deposited film formation step after exposure to heat generated by irradiation with laser light.

31: The method for manufacturing the display device according to claim 30, wherein
the display device further comprises a third pixel provided on the substrate and configured to emit light with a peak wavelength different from the peak wavelengths of the first and second pixels and a reflective electrode and a semitransparent reflective electrode provided in the third pixel,
in the second vapor-deposited film formation step, a second vapor-deposited film including a stack of the second light-emitting film and a third light-emitting film is formed over an entire surface of the substrate including the first, second, and third pixels,
in the step of removing the second vapor-deposited film including the second light-emitting film, the second vapor-deposited film including the stack of the second light-emitting film and the third light-emitting film is removed from a region other than the second and third pixels with laser light,
in the conductive light-transmissive film formation step, a conductive light-transmissive film having a predetermined thickness is formed in the second pixel to adjust a distance between the reflective electrode and the second light-emitting film in the second pixel such that light with the peak wavelength of the second pixel is output from the semitransparent reflective electrode, and a conductive light-transmissive film having a predetermined thickness is formed in the third pixel to adjust a distance between the reflective electrode and the third light-emitting film in the third pixel such that light with the peak wavelength of the third pixel is output from the semitransparent reflective electrode, and
the remaining film percentage of the vapor-deposited film formed on the first light-emitting film in the first vapor-deposited film formation step after exposure to heat generated by irradiation with laser light is higher than the remaining film percentage of the vapor-deposited film formed on the second light-emitting film in the second vapor-deposited film formation step after exposure to heat generated by irradiation with laser light, the second light-emitting film being an upper layer of the stack of the second light-emitting film and the third light-emitting film.

32: The method for manufacturing the display device according to claim 30, wherein the vapor-deposited film formed on the first light-emitting film in the first vapor-deposited film formation step is thicker than the vapor-deposited film formed on the second light-emitting film in the second vapor-deposited film formation step.

33: The method for manufacturing the display device according to claim 30, wherein the vapor-deposited film formed on the first light-emitting film in the first vapor-deposited film formation step contains at least one of an inorganic material, an inorganic metal oxide, and a crystalline organic material in a larger amount than the vapor-deposited film formed on the second light-emitting film in the second vapor-deposited film formation step.

34: The method for manufacturing the display device according to claim 30, wherein a mask configured to partially block the laser light is used in the step of removing the first vapor-deposited film or the step of removing the second vapor-deposited film.

35: The method for manufacturing the display device according to claim 30, wherein the step of removing the first vapor-deposited film or the step of removing the second vapor-deposited film is performed in a vacuum atmosphere or an atmosphere containing less than 10 ppm water and oxygen.

36: The method for manufacturing the display device according to claim 30, wherein pulsed laser light with an extremely short duration of 10⁻¹⁵ to 10⁻¹² seconds is used in the step of removing the second vapor-deposited film.

37: The method for manufacturing the display device according to claim 31, wherein the conductive light-transmissive films formed in the conductive light-transmissive film formation step have such thicknesses that the distance between the reflective electrode and the second light-emitting film in the second pixel is ¼ of the peak wavelength of the second pixel×(2N−1) (wherein N is a natural number) and that the distance between the reflective electrode and the third light-emitting film in the third pixel is ¼ of the peak wavelength of the third pixel×(2N−1) (wherein N is a natural number).

38: The method for manufacturing the display device according to claim 31, wherein
the first light-emitting film is a blue light-emitting film,
the second light-emitting film is one of a green light-emitting film and a red light-emitting film, and
the third light-emitting film is the other of the green light-emitting film and the red light-emitting film.

39: The method for manufacturing the display device according to claim 31, wherein
the first light-emitting film is a green light-emitting film,
the second light-emitting film is one of a red light-emitting film and a blue light-emitting film, and
the third light-emitting film is the other of the red light-emitting film and the blue light-emitting film.

40: The method for manufacturing the display device according to claim 31, wherein
the first light-emitting film is a red light-emitting film,
the second light-emitting film is one of a green light-emitting film and a blue light-emitting film, and
the third light-emitting film is the other of the green light-emitting film and the blue light-emitting film.

41: The method for manufacturing the display device according to claim 37, further comprising a step of providing a color filter in a path through which light with the peak wavelength of the second pixel is emitted from the second pixel, the color filter having a higher transmittance in a wavelength range of light with the peak wavelength of the second pixel than in other wavelength ranges, and providing a color filter in a path through which light with the peak wavelength of the third pixel is emitted from the third pixel, the color filter having a higher transmittance in a wavelength range of light with the peak wavelength of the third pixel than in other wavelength ranges.
